(19) United States
(12) Patent Application Publication
(10) Pub. No.: US 2024/0224555 A1
(43) Pub. Date: Jul. 4, 2024

(54) ORGANIC LIGHT EMITTING DIODE AND ORGANIC LIGHT EMITTING DEVICE COMPRISING THEREOF

(71) Applicant: LG Display Co., Ltd., Seoul (KR)

(72) Inventors: Jun-Ho LEE, Paju-si (KR); SUNG-IL WOO, Paju-si (KR); Tae-Yang LEE, Paju-si (KR); Sung-Moon KO, Paju-si (KR); Dae-Woong JEONG, Paju-si (KR)

(73) Assignee: LG Display Co., Ltd., Seoul (KR)

(21) Appl. No.: 18/383,769

(22) Filed: Oct. 25, 2023

(30) Foreign Application Priority Data
Dec. 22, 2022 (KR) 10-2022-0181918

(51) Int. Cl. H10K 50/11; C09K 11/06; H10K 85/60

(52) U.S. Cl. CPC H10K 50/11; C09K 11/06; H10K 85/6572; H10K 85/658

(57) ABSTRACT

An organic light diode (OLED) and an organic light emitting device comprising the OLED (e.g., a display device or a lighting device) are described. The OLED can comprise at least one emitting material layer including a first compound where an alkyl group is substituted to a specific position of an electron donor moiety. Luminous properties in the OLED and the device can be improved by applying the first compound with beneficial luminous efficiency.

### CROSS-REFERENCE TO RELATED APPLICATIONS

This application claims priority under 35 U.S.C. § 119(a) to Korean Patent Application No. 10-2022-0181918, filed in the Republic of Korea on Dec. 22, 2022, the entire contents of which are hereby expressly incorporated by reference into the present application.

### BACKGROUND

### Technical Field

The present disclosure relates to an organic light emitting diode, and more particularly to, an organic light emitting diode (OLED) that has beneficial luminous properties as well as an organic light emitting device including the OLED.

### Discussion of Related Art

Flat display devices including an organic light emitting diode (OLED) have been investigated as display devices that can replace a liquid crystal display device (LCD). The electrode configurations in the OLED can implement unidirectional or bidirectional images. Also, the OLED can be formed even on a flexible transparent substrate such as a plastic substrate so that a flexible or a foldable display device can be realized with ease using the OLED. In addition, the OLED can be driven at a lower voltage and the OLED has advantageous high color purity compared to the LCD.

However, there remains a need to develop OLEDs and devices including the OLEDs that have improved luminous efficiency and luminous lifespan. Since fluorescent materials use only singlet excitons in the luminous process, the related art fluorescent material shows low luminous efficiency. Meanwhile, phosphorescent materials can show high luminous efficiency since they use triplet exciton as well as singlet excitons in the luminous process. But such phosphorescent materials comprise metal complexes, which can have a luminous lifespan that is too short for commercial use. As such, there remains a need to develop an OLED with sufficient luminous properties.

### SUMMARY OF THE DISCLOSURE

Accordingly, some embodiments of the present disclosure are directed to an organic compound, an organic light emitting diode and an organic light emitting device that substantially obviate one or more of the problems due to the limitations and disadvantages of the related art.

An aspect of the present disclosure is to provide an organic light emitting diode having beneficial luminous properties as well as an organic light emitting device including the diode.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides an organic light emitting diode that comprise a first electrode; a second electrode facing the first electrode; and an emissive layer disposed between the first electrode and the second electrode, and including one or more emitting material layers, wherein at least one emitting material layer comprises a first compound, and wherein the first compound comprises an organic compound having the following structure of Chemical Formula 1:

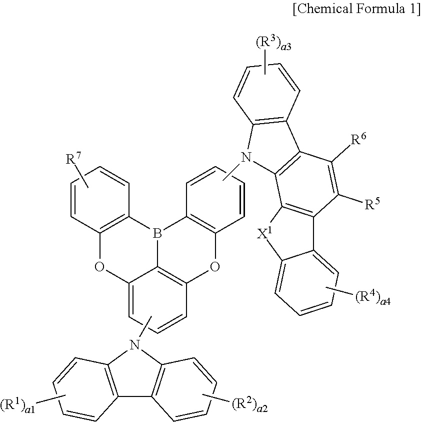

wherein, in Chemical Formula 1,
each of R¹ and R² is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹ is identical to or different from each other when a1 is 2, 3 or 4 and each R² is identical to or different from each other when a2 is 2, 3 or 4;
each of R³ and R⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R³ is identical to or different from each other when a3 is 2, 3 or 4 and each R⁴ is identical to or different from each other when a4 is 2, 3 or 4, or
optionally, two adjacent R³ when a3 is 2, 3 or 4 and/or two adjacent R⁴ when a4 is 2, 3 or 4 can be further linked to form an unsubstituted or substituted C₃-C₂₀ alicyclic ring, an unsubstituted or substituted C₃-C₂₀ hetero alicyclic ring, an unsubstituted or substituted C₆-C₃₀ aromatic ring or an unsubstituted or substituted C₃-C₂₀ hetero aromatic ring;
R⁵ is an unsubstituted or substituted C₁-C₂₀ alkyl group;
R⁶ is hydrogen, an unsubstituted or substituted C₆-C₃₀ aryl group or an unsubstituted or substituted C₃-C₃₀ hetero aryl group;
R⁷ is an unsubstituted or substituted C₆-C₃₀ aryl group or an unsubstituted or substituted C₃-C₃₀ hetero aryl group;
X¹ is CR⁹R¹⁰, NR⁹, O or S, where each of R⁹ and R¹⁰ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of a1, a2, a3 and a4 is independently 0, 1, 2, 3 or 4; and
a dotted line indicates a fused position.

The first compound can comprise an organic compound having the following structure of Chemical Formula 2:

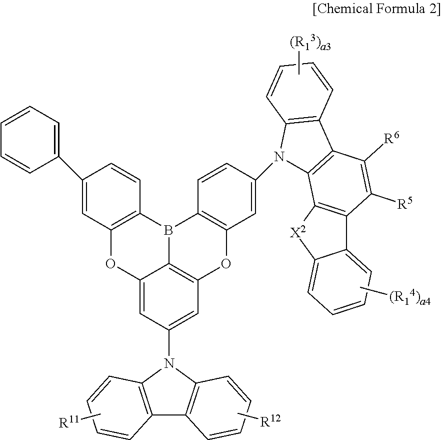

wherein, in Chemical Formula 2,
each of R⁵, R⁶, a3 and a4 is a same as defined in Chemical Formula 1;
each of R¹¹ and R¹² is independently hydrogen or an unsubstituted or substituted C₁-C₂₀ alkyl group;
each of R¹³ and R¹⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹³ is identical to or different from each other when a3 is 2, 3 or 4 and each R¹⁴ is identical to or different from each other when a4 is 2, 3 or 4, or
optionally, two adjacent R¹³ when a3 is 2, 3 or 4 and/or two adjacent R¹⁴ when a4 is 2, 3 or 4 can be further linked to form a fused ring having the following structure of Chemical Formula 3;
X² is O or S;
a dotted line indicates a position to which the ring of Chemical Formula 3 is fused,

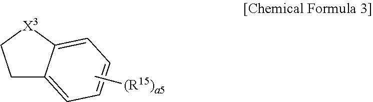

wherein, in Chemical Formula 3,
R¹⁵ is independently an unsubstituted or substituted C₁-C₂₀ alkyl group, where Each R¹⁵ is identical to or different from each other when a5 is 2, 3 or 4;
X³ is CR¹⁶R¹⁷, NR¹⁶, O or S, where each of R¹⁶ and R¹⁷ is independently an unsubstituted or substituted C₁-C₂₀ alkyl group, an unsubstituted or substituted C₆-C₃₀ aryl group or an unsubstituted or substituted C₃-C₃₀ hetero aryl group;
a5 is 0, 1, 2, 3 or 4; and
a dotted line indicates a position to which the ring of Chemical Formula 2 is fused.

The at least one emitting material layer can further comprise a second compound.

In one embodiment, the second compound can comprise an organic compound having the following structure of Chemical Formula 5:

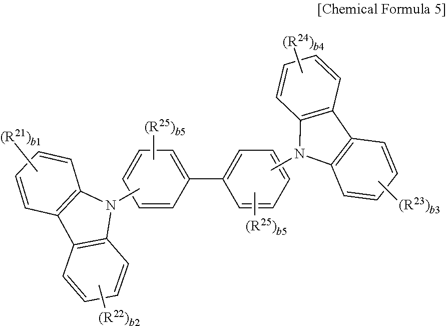

wherein, in Chemical Formulae 5,
each of R²¹, R²², R²³, R²⁴, R²⁵ and R²⁶ is independently a cyano group, an unsubstituted or substituted C₁-C₂₀ alkyl group, an unsubstituted or substituted C₆-C₃₀ aryl group or an unsubstituted or substituted C₃-C₃₀ hetero aryl group, where each R²¹ is identical to or different from each other when b1 is 2, 3 or 4, each R²² is identical to or different from each other when b2 is 2, 3 or 4, each R²³ is identical to or different from each other when b3 is 2, 3 or 4, each R²⁴ is identical to or different from each other when b4 is 2, 3 or 4, each R²¹ is identical to or different from each other when b5 is 2, 3 or 4, and each R²⁶ is identical to or different from each other when b6 is 2, 3 or 4; and
each of b1, b2, b3, b4, b5 and b6 is independently 0, 1, 2, 3 or 4.

In another embodiment, the second compound can comprise an organic compound having the following structure of Chemical Formula 7:

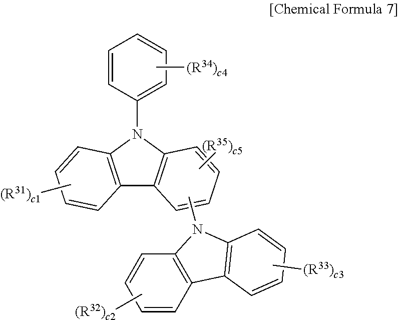

wherein, in Chemical Formula 7,
each of R³¹, R³², R³³, R³⁴ and R³⁵ is independently a cyano group, an unsubstituted or substituted C₁-C₂₀ alkyl group, an unsubstituted or substituted C₆-C₃₀ aryl group or an unsubstituted or substituted C₃-C₃₀ hetero aryl group, an unsubstituted or substituted C₆-C₃₀ triaryl methyl group, an unsubstituted or substituted C₆-C₃₀ triaryl silyl group or an unsubstituted or substituted C₆-C₃₀ triaryl germanyl group, where each R³¹ is identical to or different from each other when c1 is 2, 3 or 4, each R³² is identical to or different from each other when c2 is 2, 3 or 4, each R³³ is identical to or different from each other when c3 is 2, 3 or 4, where each R³⁴ is identical to or different from each other when c4 is 2, 3, 4 or 5, and each R³⁵ is identical to or different from each other when c5 is 2 or 3;
each of c1, c2 and c3 is independently 0, 1, 2, 3 or 4;
c4 is 0, 1, 2, 3, 4 or 5; and
c5 is 0, 1, 2 or 3.

In another embodiment, the emissive layer can comprise a first emitting part disposed between the first electrode and the second electrode; a second emitting part disposed between the first emitting part and the second electrode; and a first charge generation layer disposed between the first emitting part and the second emitting part, and wherein at least one of the first emitting part and the second emitting part can comprise the at least one emitting material layer.

As an example, the first emitting part can comprise a first emitting material layer and the first emitting material layer can comprise the at least one emitting material layer.

The second emitting part can comprise a second emitting material layer, and the second emitting material layer can comprise a first layer disposed between the first charge generation layer and the second electrode; and a second layer disposed between the first layer and the second electrode, one of the first layer and the second layer can a red emitting material layer, and the other of the first layer and the second layer can be a green emitting material layer.

Optionally, the second emitting material layer can further comprise a third layer disposed between the first layer and the second layer, and the third layer can be a yellow-green emitting material layer.

In another embodiment, the emissive layer can further comprise a third emitting part disposed between the second emitting part and the second electrode; and a second charge generation layer disposed between the second emitting part and the third emitting part.

At least one of the first emitting part and the third emitting part can comprise the at least one emitting material layer.

For example, the first emitting part can comprise a first emitting material layer and the third emitting part can comprise a third emitting material layer, and each of the first emitting material layer and the third emitting material layer can comprise the at least one emitting material layer.

In another embodiment, the second emitting part can comprise a second emitting material layer, the second emitting material layer can comprise a first layer disposed between the first charge generation layer and the second electrode; and a second layer disposed between the first layer and the second electrode, and one of the first layer and the second layer can be a red emitting material layer, and the other of the first layer and the second layer can be a green emitting material layer.

In yet another aspect, the present disclosure provides an organic light emitting device, for example, an organic light emitting display device or an organic light emitting illumination device, comprises a substrate and the organic light emitting diode over the substrate.

The first compound has delayed fluorescent properties so that triplet excitons can be converted rapidly singlet excitons by RISC. The first compound can realize Internal Quantum Efficiency of 100% using the singlet excitons generated at the first compound.

Holes and electrons can be transferred in balance to the first compound from the second compound of a host. As the charge injection efficiency and exciton generation efficiency are improved, the luminous efficiency of the OLED can be enhanced.

It is to be understood that both the foregoing general description and the following detailed description are exemplary and explanatory, and are intended to provide further explanation of the inventive concepts as claimed.

### BRIEF DESCRIPTION OF THE DRAWINGS

The accompanying drawings, which are comprised to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with one or more embodiments of the present disclosure.

FIG. 2 illustrates a cross-sectional view of an organic light emitting display device as an example of an organic light emitting device in accordance with an embodiment of the present disclosure.

FIG. 3 illustrates a cross-sectional view of an organic light emitting diode having a single emitting part in accordance with an embodiment of the present disclosure.

FIG. 4 illustrates a cross-sectional view of an organic light emitting diode having two emitting parts in accordance with another embodiment of the present disclosure.

FIG. 5 illustrates a cross-sectional view of an organic light emitting display device in accordance with another embodiment of the present disclosure.

FIG. 6 illustrates a cross-sectional view of an organic light emitting diode having a tandem structure of three emitting parts in accordance with another embodiment of the present disclosure.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts.

All the components of each organic light emitting display device according to all embodiments of the present disclosure are operatively coupled and configured.

### Organic Light Emitting Diode and Organic Light Emitting Device

The present disclosure relates to an organic light emitting diode where an emissive layer comprises a first compound that can transfer efficiently exciton energy, and optionally, a second compound as well as an organic light emitting device including the diode. As an example, in one or more embodiments of the present disclosure, the organic light emitting diode can be applied to an organic light emitting device such as an organic light emitting display device or an organic light emitting illumination device. As an example, an organic light emitting display device will be described.

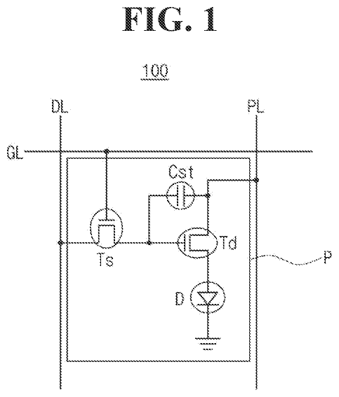

FIG. 1 illustrates a schematic circuit diagram of an organic light emitting display device in accordance with one or more embodiments of the present disclosure. As illustrated in FIG. 1, a gate line GL, a data line DL and power line PL, each of which crosses each other to define a pixel region P, are provided in an organic light emitting display device 100. A switching thin film transistor Ts, a driving thin film transistor Td, a storage capacitor Cst and an organic light emitting diode D are disposed within the pixel region P. The pixel region P can comprise a first pixel region, a second pixel region and a third pixel region. However, embodiments of the present disclosure are not limited to such examples. The organic light emitting display device 100 can comprise a plurality of such pixel regions P which can be arranged in a matrix configuration or other configurations.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

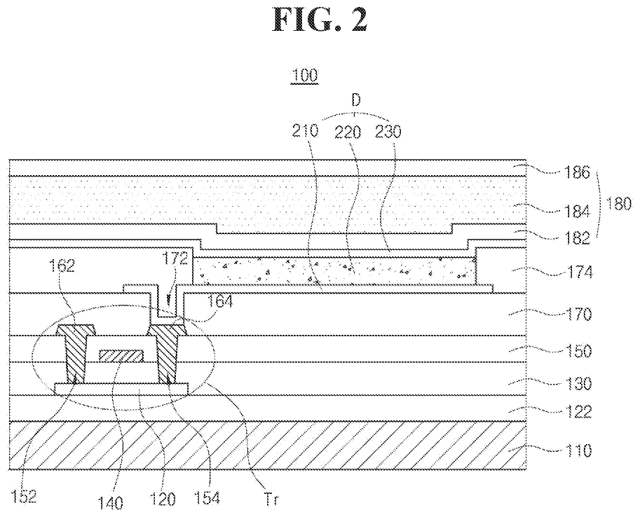

The driving thin film transistor Td is turned on by the data signal applied to a gate electrode 140 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an embodiment of the present disclosure. The pixel circuit configuration of FIG. 1 can be used in the display device of FIG. 2 or other figures of the present application.

As illustrated in FIG. 2, the organic light emitting display device 100 comprises a substrate 110, a thin-film transistor Tr on the substrate 110, and an organic light emitting diode D connected to the thin film transistor Tr.

As an example, the substrate 110 can comprise a red pixel region, a green pixel region and a blue pixel region and an organic light emitting diode D can be located in each pixel region. Each of the organic light emitting diodes D emitting red, green and blue light, respectively, is located correspondingly in the red pixel region, the green pixel region and the blue pixel region.

The substrate 110 can comprise, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 110, on which the thin film transistor Tr and the organic light emitting diode D are arranged, forms an array substrate.

A buffer layer 122 can be disposed on the substrate 110. The thin film transistor Tr can be disposed on the buffer layer 122. In certain embodiments, the buffer layer 122 can be omitted.

A semiconductor layer 120 is disposed on the buffer layer 122. In one embodiment, the semiconductor layer 120 can comprise, but is not limited to, oxide semiconductor materials. In this case, a light-shield pattern can be disposed under the semiconductor layer 120, and the light-shield pattern can prevent light from being incident toward the semiconductor layer 120, thereby, preventing or reducing the semiconductor layer 120 from being degraded by the light.

Alternatively, the semiconductor layer 120 can comprise polycrystalline silicon. In this case, opposite edges of the semiconductor layer 120 can be doped with impurities.

A gate insulating layer 130 including an insulating material is disposed on the semiconductor layer 120. The gate insulating layer 130 can comprise, but is not limited to, an inorganic insulating material such as silicon oxide (SiOₓ, wherein 0<x≤2) or silicon nitride (SiNₓ, wherein 0<x≤2).

A gate electrode 140 made of a conductive material such as a metal is disposed on the gate insulating layer 130 so as to correspond to a center of the semiconductor layer 120. While the gate insulating layer 130 is disposed on the entire area of the substrate 110 as shown in FIG. 2, the gate insulating layer 130 can be patterned identically as the gate electrode 140.

An interlayer insulating layer 150 including an insulating material is disposed on the gate electrode 140 and covers an entire surface of the substrate 110. The interlayer insulating layer 150 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 150 has first and second semiconductor layer contact holes 152 and 154 that expose or do not cover a portion of the surface nearer to the opposing ends than to a center of the semiconductor layer 120. The first and second semiconductor layer contact holes 152 and 154 are disposed on opposite sides of the gate electrode 140 and spaced apart from the gate electrode 140. The first and second semiconductor layer contact holes 152 and 154 are formed within the gate insulating layer 130 and the interlayer insulating layer 150 in FIG. 2. Alternatively, in certain embodiments, the first and second semiconductor layer contact holes 152 and 154 can be formed only within the interlayer insulating layer 150 when the gate insulating layer 130 is patterned identically as the gate electrode 140.

A source electrode 162 and a drain electrode 164, which are made of conductive material such as a metal, are disposed on the interlayer insulating layer 150. The source electrode 162 and the drain electrode 164 are spaced apart from each other on opposing sides of the gate electrode 140, and contact both sides of the semiconductor layer 120 through the first and second semiconductor layer contact holes 152 and 154, respectively.

The semiconductor layer 120, the gate electrode 140, the source electrode 162 and the drain electrode 164 constitute the thin film transistor Tr, which acts as a driving element. The thin film transistor Tr in FIG. 2 has a coplanar structure in which the gate electrode 140, the source electrode 162 and the drain electrode 164 are disposed on the semiconductor layer 120. Alternatively, the thin film transistor Tr can have an inverted staggered structure in which a gate electrode is disposed under a semiconductor layer and a source and drain electrodes are disposed on the semiconductor layer. In this case, the semiconductor layer can comprise amorphous silicon.

The gate line GL and the data line DL, which cross each other to define a pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr can further comprise a storage capacitor Cst configured to constantly keep a voltage of the gate electrode 140 for one frame.

A passivation layer 170 is disposed on the source and drain electrodes 162 and 164. The passivation layer 170 covers the thin film transistor Tr on the entire substrate 110. The passivation layer 170 has a flat top surface and a drain contact hole (or a contact hole) 172 that exposes or does not cover the drain electrode 164 of the thin film transistor Tr. While the drain contact hole 172 is disposed on the second semiconductor layer contact hole 154, it can be spaced apart from the second semiconductor layer contact hole 154.

The organic light emitting diode (OLED) D comprises a first electrode 210 that is disposed on the passivation layer 170 and connected to the drain electrode 164 of the thin film transistor Tr. The OLED D further comprises an emissive layer 220 and a second electrode 230 each of which is disposed sequentially on the first electrode 210.

The first electrode 210 is disposed separately in each pixel region P. The first electrode 210 can be an anode and comprise conductive material having relatively high work function value. For example, the first electrode 210 can comprise a transparent conductive oxide (TCO). More particularly, the first electrode 210 can comprise, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

In one embodiment, when the organic light emitting display device 100 is a bottom-emission type, the first electrode 210 can have a single-layered structure of the TCO. Alternatively, when the organic light emitting display device 100 is a top-emission type, a reflective electrode or a reflective layer can be disposed under the first electrode 210. For example, the reflective electrode or the reflective layer can comprise, but is not limited to, silver (Ag) or aluminum-palladium-copper (APC) alloy. In the OLED D of the top-emission type, the first electrode 210 can have a triple-layered structure of ITO/Ag/ITO or ITO/APC/ITO.

In addition, a bank layer 174 is disposed on the passivation layer 170 in order to cover edges of the first electrode 210. The bank layer 174 exposes or does not cover a center of the first electrode 210 corresponding to each pixel region. In certain embodiments, the bank layer 174 can be omitted.

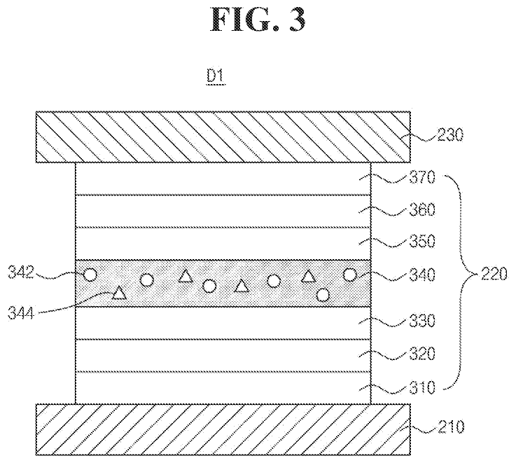

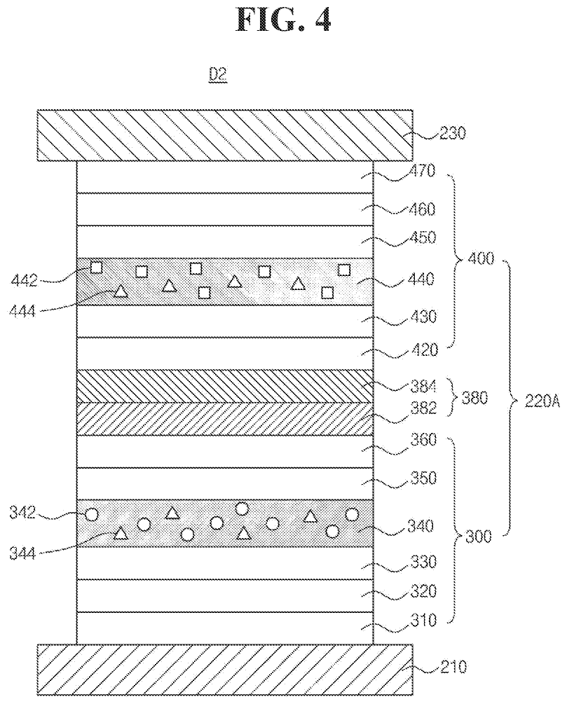

An emissive layer 220 is disposed on the first electrode 210. In one embodiment, the emissive layer 220 can have a single-layered structure of an emitting material layer (EML). Alternatively, the emissive layer 220 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL). In one embodiment, the emissive layer 220 can have a single emitting part (FIG. 3). Alternatively, the emissive layer 220 can have multiple emitting parts to form a tandem structure (FIG. 4). For example, the emissive layer 220 can be applied to an OLED with a single emitting part located each of the red pixel region, the green pixel region and the blue pixel region. Alternatively, the emissive layer 220 can be applied to a tandem-type OLED where at least two emitting parts are stacked.

The emissive layer 220 can comprise a first compound having delayed fluorescent properties, and optionally, a second compound of a host. The luminous efficiency and the luminous lifespan of the OLED D and the organic light emitting display device 100 can be improved.

The second electrode 230 is disposed on the substrate 110 above which the emissive layer 220 is disposed. The second electrode 230 can be disposed on the entire display area. The second electrode 230 can comprise a conductive material with a relatively low work function value compared to the first electrode 210. The second electrode 230 can be a cathode providing electrons. For example, the second electrode 230 can comprise at least one of, but is not limited to, aluminum (Al), magnesium (Mg), calcium (Ca), silver (Ag), alloy thereof and/or combinations thereof such as aluminum-magnesium alloy (Al—Mg). When the organic light emitting display device 100 is a top-emission type, the second electrode 230 is thin so as to have light-transmissive (semi-transmissive) property.

In addition, an encapsulation film 180 can be disposed on the second electrode 230 in order to prevent or reduce outer moisture from penetrating into the OLED D. The encapsulation film 180 can have, but is not limited to, a laminated structure of a first inorganic insulating film 182, an organic insulating film 184 and a second inorganic insulating film 186. In certain embodiments, the encapsulation film 180 can be omitted.

A polarizing plate can be attached onto the encapsulation film 180 to reduce reflection of external light. For example, the polarizing plate can be a circular polarizing plate. When the organic light emitting display device 100 is a bottom-emission type, the polarizing plate can be disposed under the substrate 110. Alternatively, when the organic light emitting display device 100 is a top-emission type, the polarizing plate can be disposed on the encapsulation film 180. In addition, a cover window can be attached to the encapsulation film 180 or the polarizing plate. In this case, the substrate 110 and the cover window can have a flexible property, thus the organic light emitting display device 100 can be a flexible display device.

The OLED D is described in more detail. FIG. 3 illustrates a schematic cross-sectional view of an organic light emitting diode having a single emitting part in accordance with an embodiment of the present disclosure. For instance, FIG. 3 shows an example (OLED D1) of the OLED D in FIGS. 1 and 2.

As illustrated in FIG. 3, the organic light emitting diode (OLED) D1 in accordance with an example of the present disclosure comprises first and second electrodes 210 and 230 facing each other and an emissive layer 220 disposed between the first and second electrodes 210 and 230. The organic light emitting display device 100 comprises a red pixel region, a green pixel region and a blue pixel region, and the OLED D1 can be disposed in the red pixel region, the green pixel region and/or the blue pixel region. As an example, the OLED D1 can be disposed in the blue pixel region.

In an embodiment, the emissive layer 220 comprises an emitting material layer (EML) 340 disposed between the first and second electrodes 210 and 230. The EML 340 can be a blue emitting material layer.

The emissive layer 220 can comprise at least one of a hole transport layer (HTL) 320 disposed between the first electrode 210 and the EML 340 and an electron transport layer (ETL) 360 disposed between the second electrode 230 and the EML 340. In certain embodiments, the emissive layer 220 can further comprise at least one of a hole injection layer (HIL) 310 disposed between the first electrode 210 and the HTL 320 and an electron injection layer (EIL) 370 disposed between the second electrode 230 and the ETL 360. Alternatively, the emissive layer 220 can further comprise a first exciton blocking layer, i.e., an electron blocking layer (EBL) 330 disposed between the HTL 320 and the EML 340 and/or a second exciton blocking layer, i.e., a hole blocking layer (HBL) 350 disposed between the EML 340 and the ETL 360.

The first electrode 210 can be an anode that provides holes into the EML 340. The first electrode 210 can comprise a conductive material having a relatively high work function value, for example, a transparent conductive oxide (TCO). In an embodiment, the first electrode 210 can comprise, but is not limited to, ITO, IZO, ITZO, SnO, ZnO, ICO, AZO, and/or combinations thereof.

The second electrode 230 can be a cathode that provides electrons into the EML 340. The second electrode 230 can comprise a conductive material having a relatively low work function values, i.e., a highly reflective material such as Al, Mg, Ca, Ag, and/or alloy thereof and/or combinations thereof such as Al—Mg.

The EML 340 comprises a first compound 342, and optionally, a second compound 344. The first compound 342 can be delayed fluorescent material and the second compound 344 can be a host.

The first compound 342 having the delayed fluorescent properties can comprise a first moiety that can be an electron acceptor group consisting of polycyclic ring including an oxygen atom and a boron atom, and a second moiety that can be plural electron donor groups (EDG) each of which including a carbazole moiety. The first compound can have the following structure of Chemical Formula 1:

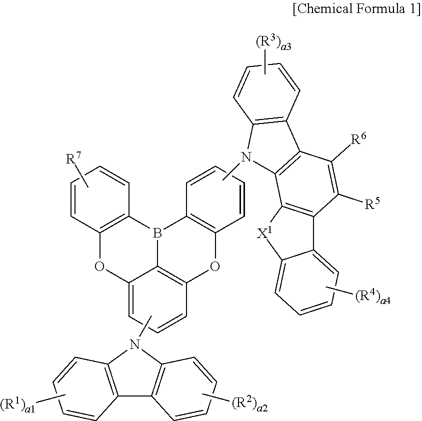

wherein, in Chemical Formula 1,
each of R¹ and R² is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹ is identical to or different from each other when a1 is 2, 3 or 4 and each R² is identical to or different from each other when a2 is 2, 3 or 4;
each of R³ and R⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R³ is identical to or different from each other when a3 is 2, 3 or 4 and each R⁴ is identical to or different from each other when a4 is 2, 3 or 4, or
optionally, two adjacent R³ when a3 is 2, 3 or 4 and/or two adjacent R⁴ when a4 is 2, 3 or 4 can be further linked to form an unsubstituted or substituted C₃-C₂₀ alicyclic ring, an unsubstituted or substituted C₃-C₂₀ hetero alicyclic ring, an unsubstituted or substituted C₆-C₃₀ aromatic ring or an unsubstituted or substituted C₃-C₂₀ hetero aromatic ring;
R⁵ is an unsubstituted or substituted C₁-C₂₀ alkyl group;
R⁶ is hydrogen, an unsubstituted or substituted C₆-C₃₀ aryl group or an unsubstituted or substituted C₃-C₃₀ hetero aryl group;
R⁷ is an unsubstituted or substituted C₆-C₃₀ aryl group or an unsubstituted or substituted C₃-C₃₀ hetero aryl group;
X¹ is CR⁹R¹⁰, NR⁹, O or S, where each of R⁹ and R¹⁰ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of a1, a2, a3 and a4 is independently 0, 1, 2, 3 or 4; and
a dotted line indicates a fused position.

As used herein, the term “unsubstituted” means that hydrogen is directly linked to a carbon atom. “Hydrogen”, as used herein, can refer to protium and/or deuterium.

As used herein, “substituted” means that the hydrogen is replaced with a substituent. The substituent can comprise, but is not limited to, an unsubstituted or substituted C₁-C₂₀ alkyl group, an unsubstituted or substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, an unsubstituted or substituted C₁-C₁₀ alkyl silyl group, an unsubstituted or substituted C₁-C₁₀ alkoxy silyl group, an unsubstituted or substituted C₃-C₂₀ cyclo alkyl silyl group, an unsubstituted or substituted C₆-C₃₀ aryl silyl group, an unsubstituted or substituted C₃-C₃₀ hetero aryl silyl group, an unsubstituted or substituted C₆-C₃₀ aryl group, an unsubstituted or substituted C₃-C₃₀ hetero aryl group, or any combination of these groups.

For example, the substituent of the C₆-C₃₀ aryl group, the C₃-C₃₀ hetero aryl group, the C₆-C₃₀ aryl amino group, the C₃-C₃₀ hetero aryl amino group, the C₆-C₃₀ aromatic ring and the C₃-C₃₀ heteroaromatic ring can comprise at least one of a C₁-C₂₀ alkyl group, a C₆-C₃₀ aryl group, a C₃-C₃₀ hetero aryl group, a C₆-C₃₀₀ aryl amino group and a C₃-C₃₀ hetero aryl amino group.

As used herein, the term “hetero” in terms such as “a hetero aromatic group”, “a hetero cyclo alkylene group”, “a hetero arylene group”, “a hetero aryl alkylene group”, “a hetero aryl oxylene group”, “a hetero cyclo alkyl group”, “a hetero aryl group”, “a hetero aryl alkyl group”, “a hetero aryl oxy group”, “a hetero aryl amino group” and the likes means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

As used herein, the C₁-C₂₀ alkyl group can be a C₁-C₁₀ alkyl group, particularly a C₁-C₆ alkyl group, and can comprise, but is not limited to, methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, and the like.

As used herein, the C₆-C₃₀ aryl group can comprise, but is not limited to, an unfused or fused aryl group such as phenyl, biphenylyl, terphenylyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl. The C₆-C₃₀ arylene group can comprise, but is not limited to, any bivalent linking group corresponding to the above aryl group.

As used herein, the C₃-C₃₀ hetero aryl group can comprise, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthalzinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl. The C₃-C₃₀ hetero arylene group can comprise, but is not limited to, any bivalent linking group corresponding to the hetero above aryl group.

The polycyclic ring including the oxygen and boron atoms acts as the electron acceptor group and the carbazole ring and/or the fused carbazole ring acts as the electron donor group so that the organic compound having the structure of Chemical Formula 1 can have delayed fluorescent properties. Particularly, one of carbazole moiety among the electron donor moieties in Chemical Formula 1 can be further fused so that the electron donor group can be separated from the electron acceptor group within the molecule.

The organic compound having the structure of Chemical Formula 1 has very narrow energy bandgap (difference) ΔE_{ST} between its excited singlet energy level S₁ and its triplet energy level T₁ so that it can exhibit beneficial delayed fluorescent property. In one embodiment, the organic compound having the structure of Chemical Formula 1 can have maximum photoluminescence wavelength PLₘₐₓ of about 450 nm or less.

As the exciton energy transfers sufficiently to the first compound 342 from the second compound 344 because the first compound 342 having the delayed fluorescent properties has beneficial luminous property, the OLED D1 with excellent luminous properties can be realized.

The electron donor group with fused plural rings has large volume, so that steric hindrance among those moieties can be induced in the first compound 342 having the structure of Chemical Formula 1. Also, steric hindrance among those electron donor groups can be induced by arranging adjacently those electron donor moieties with large volume, and thus, the first compound 342 can have further enhanced delayed fluorescent properties.

Since the first compound 342 has very narrow energy difference ΔE_{ST} between its excited singlet energy level S₁ and its triplet energy level T₁, exciton energy transfer between singlet and triplet excitons can be occurred by RISC (Reverse Inter-Crossing System) in the first compound 342 as spin-orbital coupling (SOC) is enhanced.

The first compound 342 having the structure of Chemical Formula 1 has beneficial delayed fluorescent properties. In addition, the first compound 342 has proper luminous properties such as a singlet energy level, a triplet energy level, a highest occupied molecular orbital (HOMO) energy level and a lowest unoccupied molecular orbital (LUMO) energy level to implement excellent luminous properties. The EML 340 comprises the organic compound having the structure of Chemical Formula 1 as the first compound of an emitter (dopant) so that the OLED D1 having beneficial luminous efficiency and color purity can be realized.

In one embodiment, each of the C₆-C₃₀ aryl group, the C₃-C₃₀ hetero aryl group, the C₃-C₂₀ alicyclic ring, the C₃-C₂₀ hetero alicyclic ring, the C₆-C₃₀ aromatic ring and the C₃-C₂₀ hetero aromatic ring, which can be R¹ to R⁴ and R⁶ to R¹⁰ in Chemical Formula 1, can be independently unsubstituted or substituted with at least one group of C₁-C₁₀ alkyl (e.g., C₁-C₅ alkyl such as methyl and tert-butyl), C₆-C₃₀ aryl (e.g., C₆-Cis aryl such as phenyl) and C₃-C₃₀ hetero aryl (e.g., C₃-Cis hetero aryl such as pyridyl).

In one embodiment, each of R¹ and R² can be a C₁-C₁₀ alkyl group (e.g., methyl) and/or each of a1 and a2 can be 0 or 1 in Chemical Formula 1. When R³ and R⁴ in Chemical Formula 1 does not form the fused alicyclic ring, the fused hetero alicyclic ring, the fused aromatic ring and/or the fused hetero aromatic ring, each of R³ and R⁴ can be independently a C₁-C₁₀ alkyl group (e.g., methyl) or a C₆-C₃₀ aryl group (e.g., phenyl) and/or each of a3 and a4 can be 0, 1 or 2.

In another embodiment, two adjacent R³ and/or two adjacent R⁴ in Chemical Formula 1 can be further linked together to form a C₆-C₂₀ fused aromatic ring and/or a C₃-C₂₀ fused hetero aromatic ring. For example, the fused aromatic ring and/or the fused hetero aromatic ring by two adjacent groups can comprise, but is not limited to, an unsubstituted or substituted benzene ring, an unsubstituted or substituted naphthalene ring, an unsubstituted or substituted anthracene ring, an unsubstituted or substituted phenanthrene ring, an unsubstituted or substituted indene ring, an unsubstituted or substituted fluorene ring, an unsubstituted or substituted pyridine ring, an unsubstituted or substituted pyrimidine ring, an unsubstituted or substituted triazine ring, an unsubstituted or substituted quinoline ring, an unsubstituted or substituted iso-quinoline ring, an unsubstituted or substituted quinazoline ring, an unsubstituted or substituted quinoxaline ring, an unsubstituted or substituted indole ring, an unsubstituted or substituted benzo-furan ring, an unsubstituted or substituted benzo-thiophene ring, an unsubstituted or substituted dibenzo-furan ring, an unsubstituted or substituted dibenzo-thiophene ring and/or combinations thereof.

In one embodiment, R⁵ can be a C₁-C₁₀ alkyl group (e.g., methyl or tert-butyl), R⁶ can be hydrogen or a C₆-C₃₀ aryl group (e.g., phenyl), R⁷ can be a C₆-C₃₀ aryl group (e.g., phenyl) and/or X¹ can be O or S in Chemical Formula 1. As an example, the first compound 342 can comprise an organic compound having the structure of Chemical Formula 2:

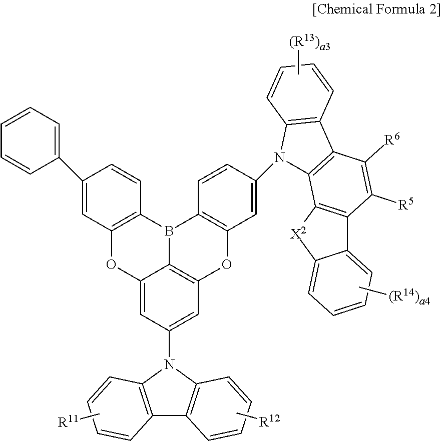

wherein, in Chemical Formula 2,
each of R⁵, R⁶, a3 and a4 is a same as defined in Chemical Formula 1;
each of R¹ and R¹² is independently hydrogen or an unsubstituted or substituted C₁-C₂₀ alkyl group;
each of R³ and R¹⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹³ is identical to or different from each other when a3 is 2, 3 or 4 and each R¹⁴ is identical to or different from each other when a4 is 2, 3 or 4, or
optionally, two adjacent R¹³ when a3 is 2, 3 or 4 and/or two adjacent R¹⁴ when a4 is 2, 3 or 4 can be further linked to form a fused ring having the following structure of Chemical Formula 3;
X² is O or S;
a dotted line indicates a portion to which the ring of Chemical Formula 3 is fused,

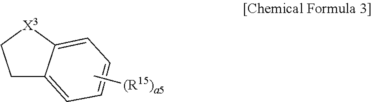

wherein, in Chemical Formula 3,
R¹⁵ is independently an unsubstituted or substituted C₁-C₂₀ alkyl group, where each R¹⁵ is identical to or different from each other when a5 is 2, 3 or 4;
X³ is CR¹⁶R¹⁷, NR¹⁶, O or S, where each of R¹⁶ and R¹⁷ is independently an unsubstituted or substituted C₁-C₂₀ alkyl group, an unsubstituted or substituted C₆-C₃₀ aryl group or an unsubstituted or substituted C₃-C₃₀ hetero aryl group;
a5 is 0, 1, 2, 3 or 4; and
a dotted line indicates a position to which the ring of Chemical Formula 2 is fused.

As an example, R¹¹ can be linked to one of position 5, position 6 and position 7 of the carbazole ring and R¹² can be linked to one of position 2, position 3 and position 4 of the carbazole ring. In one embodiment, a5 can be 0, and/or X³ can be CR¹⁶R¹⁷ where each of R¹⁶ and R¹⁷ can be independently a C₁-C₁₀ alkyl group (e.g., methyl). More particularly, the first compound 342 can be, but is not limited to, at least one of the following organic compounds of Chemical Formula 4:

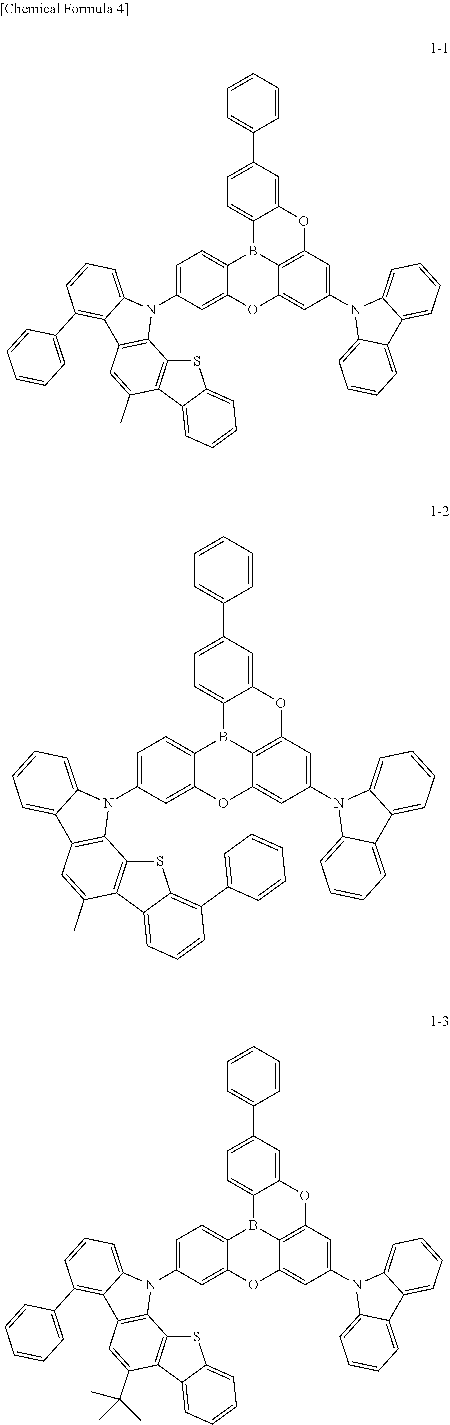 [SMILES: Cc1cc2c3c(-c4ccccc4)cccc3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3c(-c4ccccc4)cccc3c12 ; CC(C)(C)c1cc2c3c(-c4ccccc4)cccc3n(-c3ccc4c(c3)Oc3cc(-n5c6ccccc6c6ccccc65)cc5c3B4c3ccc(-c4ccccc4)cc3O5)c2c2sc3ccccc3c12]

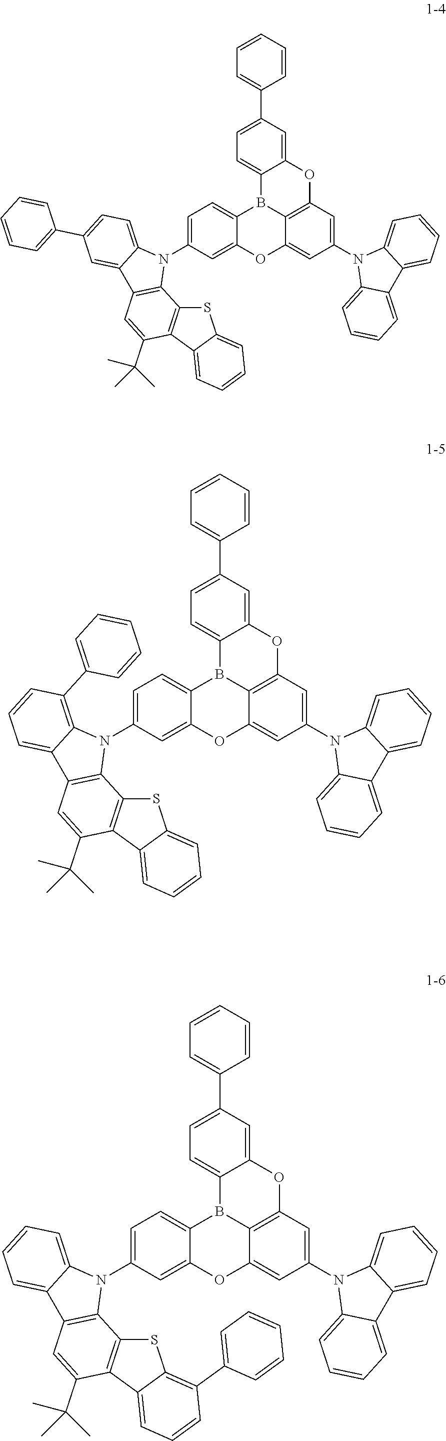 [SMILES: CC(C)(C)c1cc2c3cc(-c4ccccc4)ccc3n(-c3ccc4c(c3)Oc3cc(-n5c6ccccc6c6ccccc65)cc5c3B4c3ccc(-c4ccccc4)cc3O5)c2c2sc3ccccc3c12 ; CC(C)(C)c1cc2c3cccc(-c4ccccc4)c3n(-c3ccc4c(c3)Oc3cc(-n5c6ccccc6c6ccccc65)cc5c3B4c3ccc(-c4ccccc4)cc3O5)c2c2sc3ccccc3c12 ; CC(C)(C)c1cc2c3ccccc3n(-c3ccc4c(c3)Oc3cc(-n5c6ccccc6c6ccccc65)cc5c3B4c3ccc(-c4ccccc4)cc3O5)c2c2sc3c(-c4ccccc4)cccc3c12]

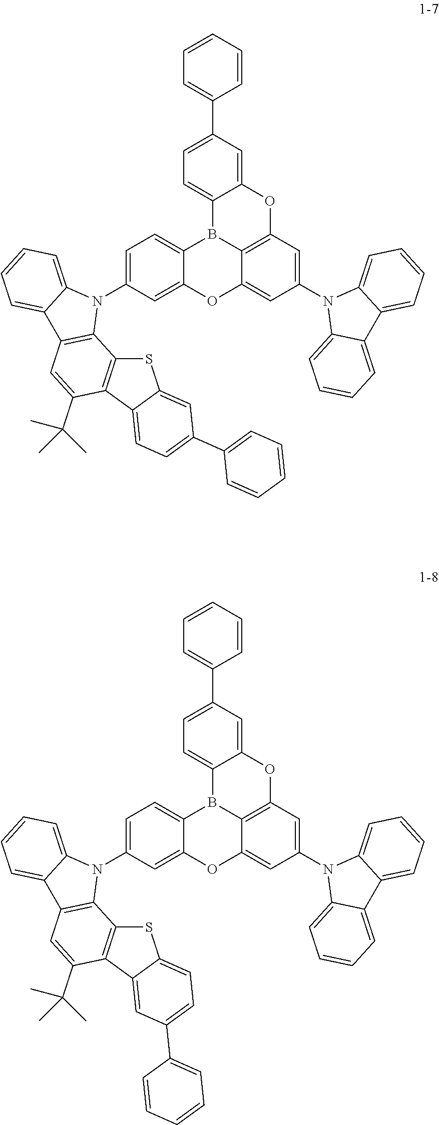 [SMILES: CC(C)(C)c1cc2c3ccccc3n(-c3ccc4c(c3)Oc3cc(-n5c6ccccc6c6ccccc65)cc5c3B4c3ccc(-c4ccccc4)cc3O5)c2c2sc3cc(-c4ccccc4)ccc3c12 ; CC(C)(C)c1cc2c3ccccc3n(-c3ccc4c(c3)Oc3cc(-n5c6ccccc6c6ccccc65)cc5c3B4c3ccc(-c4ccccc4)cc3O5)c2c2sc3ccc(-c4ccccc4)cc3c12]

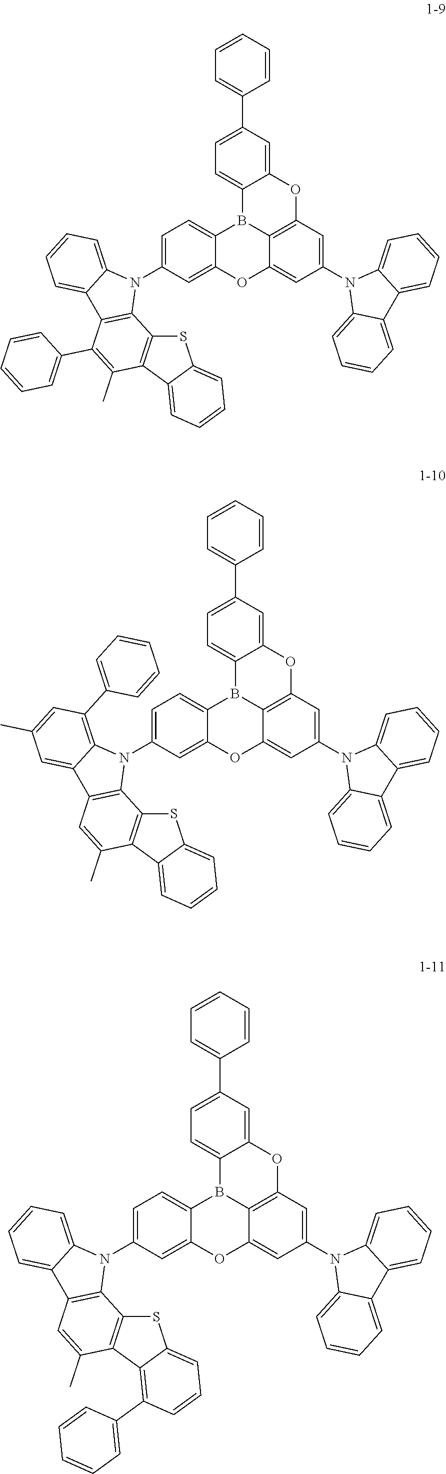 [SMILES: Cc1c(-c2ccccc2)c2c3ccccc3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc(-c2ccccc2)c2c(c1)c1cc(C)c3c4ccccc4sc3c1n2-c1ccc2c(c1)Oc1cc(-n3c4ccccc4c4ccccc43)cc3c1B2c1ccc(-c2ccccc2)cc1O3 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3cccc(-c4ccccc4)c3c12]

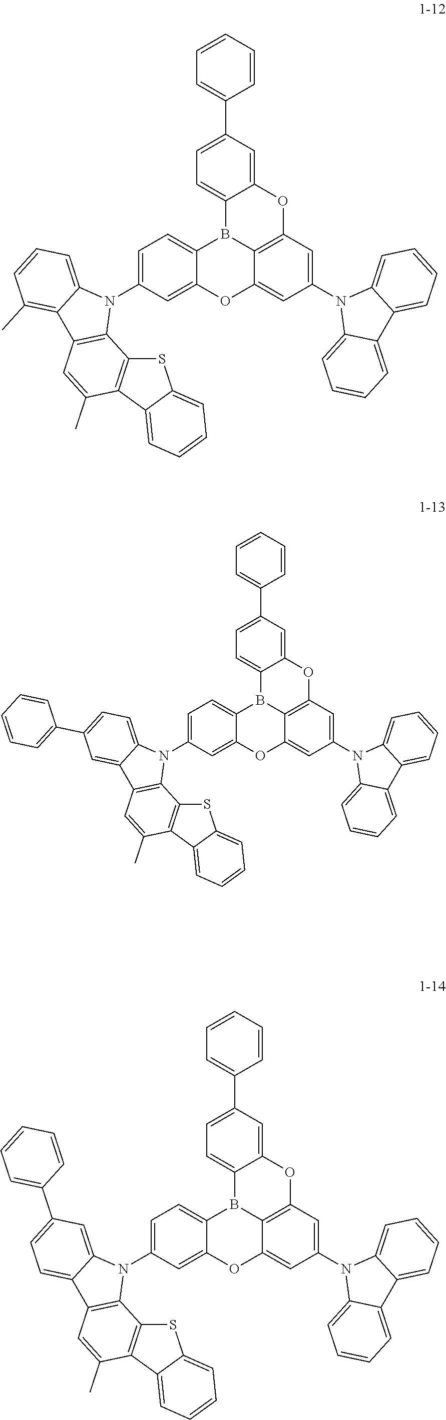 [SMILES: Cc1cc2c3c(C)cccc3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3cc(-c4ccccc4)ccc3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3ccc(-c4ccccc4)cc3n(-c3ccc4c(c3)Oc3cc(-n5c6ccccc6c6ccccc65)cc5c3B4c3ccc(-c4ccccc4)cc3O5)c2c2sc3ccccc3c12]

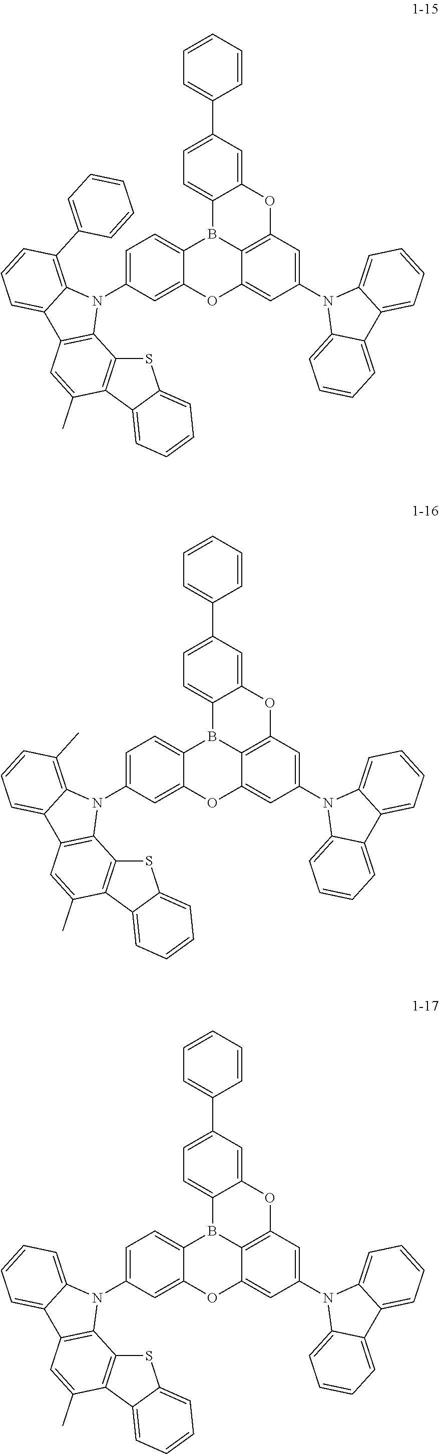 [SMILES: Cc1cc2c3cccc(-c4ccccc4)c3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3cccc(C)c3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3ccccc3c12]

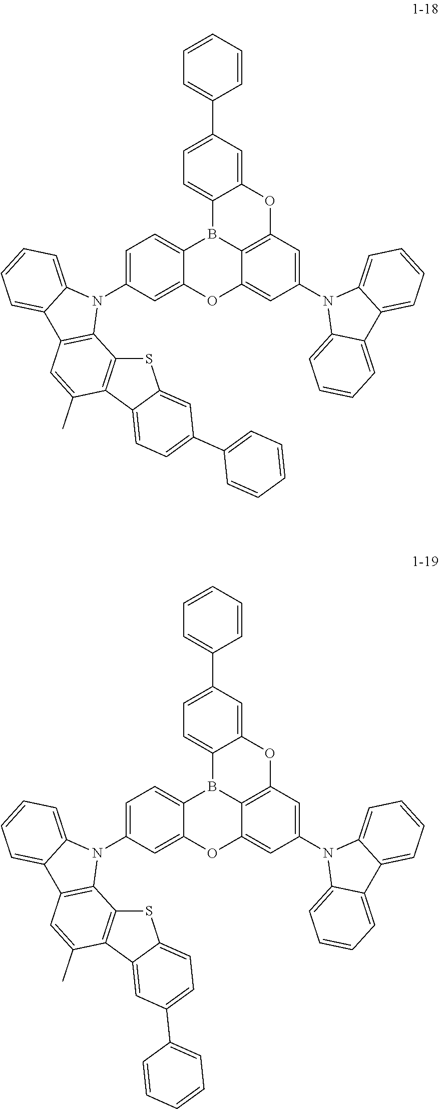 [SMILES: Cc1cc2c3ccccc3n(-c3ccc4c(c3)Oc3cc(-n5c6ccccc6c6ccccc65)cc5c3B4c3ccc(-c4ccccc4)cc3O5)c2c2sc3cc(-c4ccccc4)ccc3c12 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3ccc(-c4ccccc4)cc3c12]

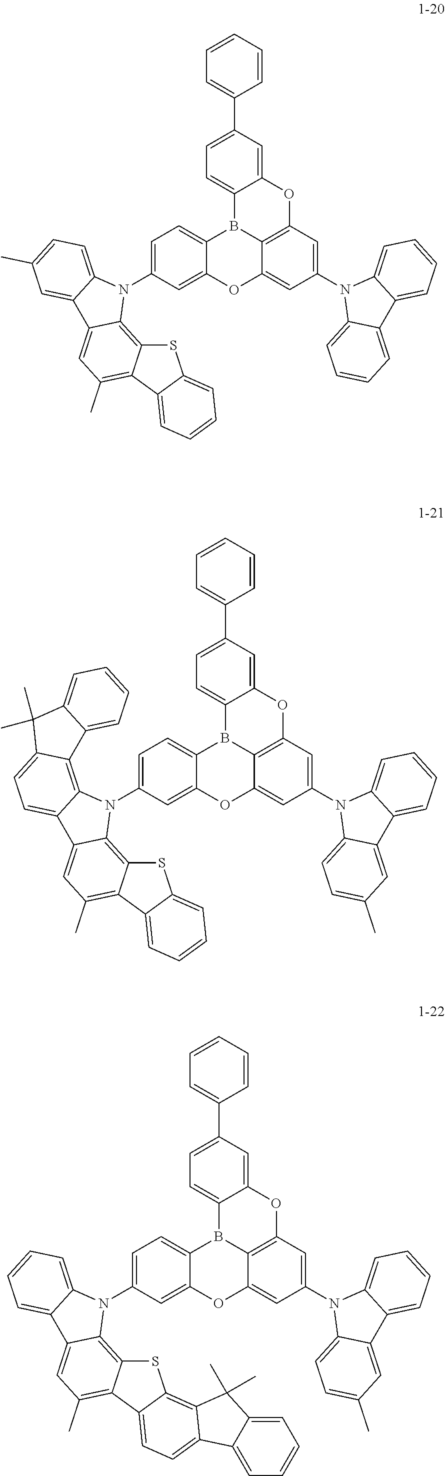 [SMILES: Cc1ccc2c(c1)c1cc(C)c3c4ccccc4sc3c1n2-c1ccc2c(c1)Oc1cc(-n3c4ccccc4c4ccccc43)cc3c1B2c1ccc(-c2ccccc2)cc1O3 ; Cc1ccc2c(c1)c1ccccc1n2-c1cc2c3c(c1)Oc1cc(-n4c5c6c(ccc5c5cc(C)c7c8ccccc8sc7c54)C(C)(C)c4ccccc4-6)ccc1B3c1ccc(-c3ccccc3)cc1O2 ; Cc1ccc2c(c1)c1ccccc1n2-c1cc2c3c(c1)Oc1cc(-n4c5ccccc5c5cc(C)c6c7ccc8c(c7sc6c54)C(C)(C)c4ccccc4-8)ccc1B3c1ccc(-c3ccccc3)cc1O2]

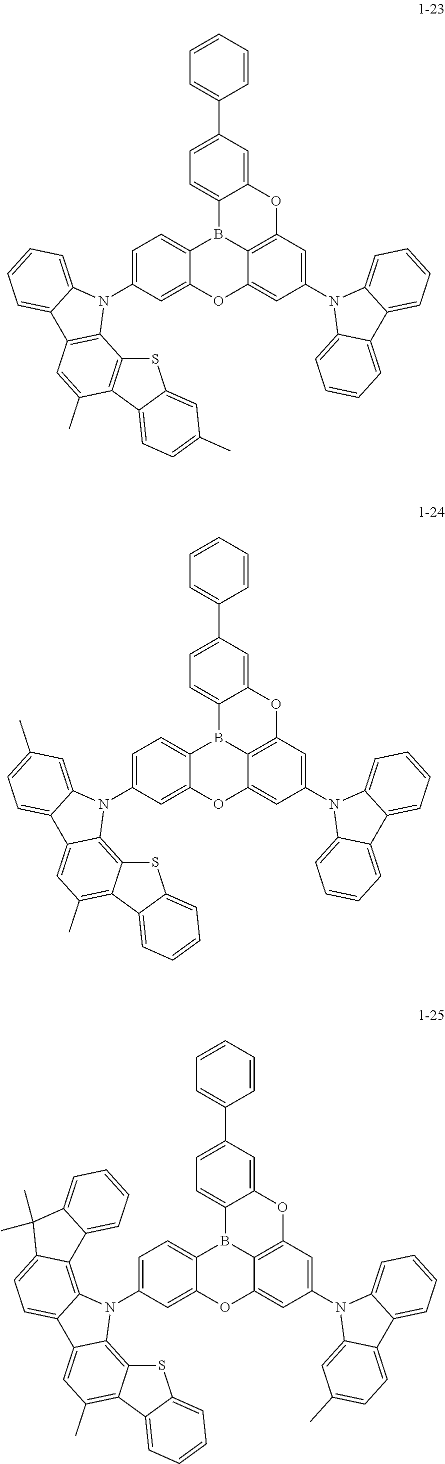 [SMILES: Cc1ccc2c(c1)sc1c2c(C)cc2c3ccccc3n(-c3ccc4c(c3)Oc3cc(-n5c6ccccc6c6ccccc65)cc5c3B4c3ccc(-c4ccccc4)cc3O5)c21 ; Cc1ccc2c3cc(C)c4c5ccccc5sc4c3n(-c3ccc4c(c3)Oc3cc(-n5c6ccccc6c6ccccc65)cc5c3B4c3ccc(-c4ccccc4)cc3O5)c2c1 ; Cc1ccc2c3ccccc3n(-c3cc4c5c(c3)Oc3cc(-n6c7c8c(ccc7c7cc(C)c9c%10ccccc%10sc9c76)C(C)(C)c6ccccc6-8)ccc3B5c3ccc(-c5ccccc5)cc3O4)c2c1]

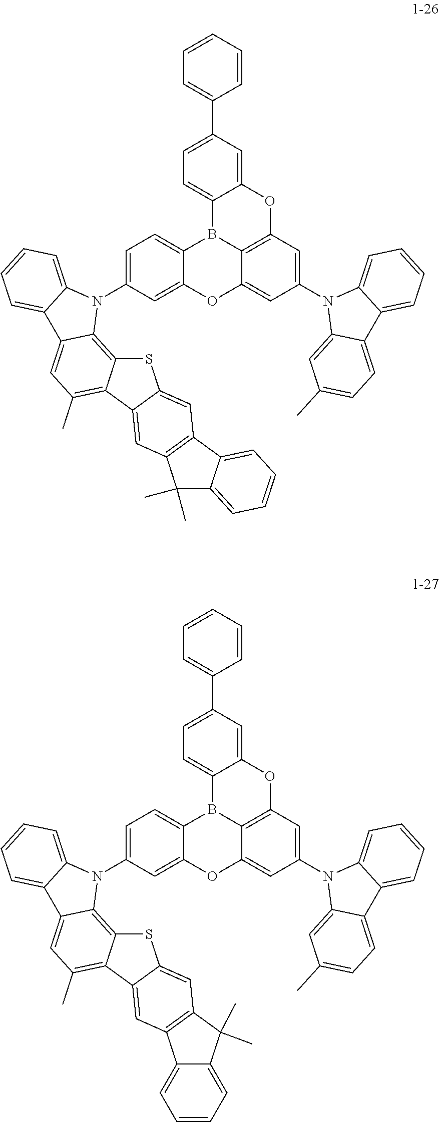 [SMILES: Cc1ccc2c3ccccc3n(-c3cc4c5c(c3)Oc3cc(-n6c7ccccc7c7cc(C)c8c9cc%10c(cc9sc8c76)-c6ccccc6C%10(C)C)ccc3B5c3ccc(-c5ccccc5)cc3O4)c2c1 ; Cc1ccc2c3ccccc3n(-c3cc4c5c(c3)Oc3cc(-n6c7ccccc7c7cc(C)c8c9cc%10c(cc9sc8c76)C(C)(C)c6ccccc6-%10)ccc3B5c3ccc(-c5ccccc5)cc3O4)c2c1]

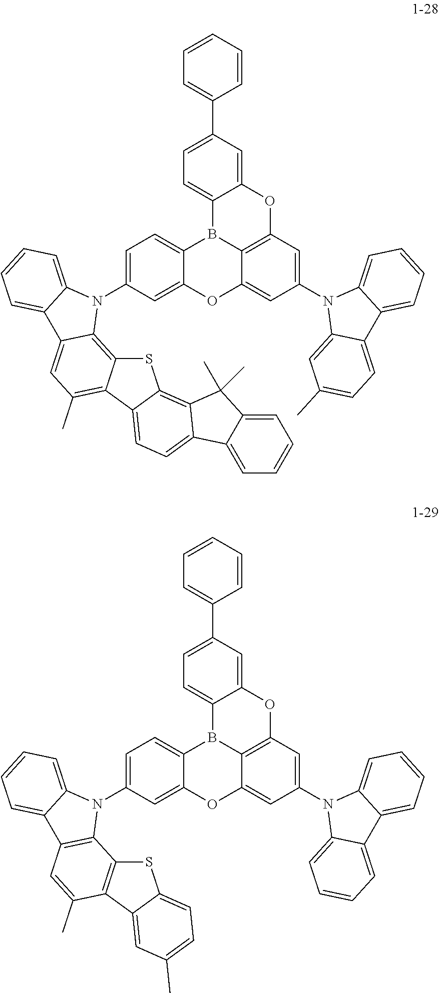 [SMILES: Cc1ccc2c3ccccc3n(-c3cc4c5c(c3)Oc3cc(-n6c7ccccc7c7cc(C)c8c9ccc%10c(c9sc8c76)C(C)(C)c6ccccc6-%10)ccc3B5c3ccc(-c5ccccc5)cc3O4)c2c1 ; Cc1ccc2sc3c(c(C)cc4c5ccccc5n(-c5ccc6c(c5)Oc5cc(-n7c8ccccc8c8ccccc87)cc7c5B6c5ccc(-c6ccccc6)cc5O7)c43)c2c1]

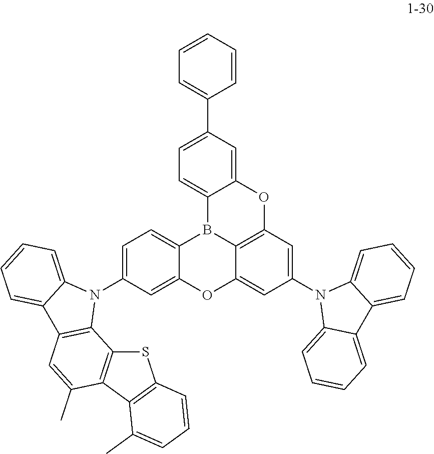 [SMILES: Cc1cccc2sc3c(c(C)cc4c5ccccc5n(-c5ccc6c(c5)Oc5cc(-n7c8ccccc8c8ccccc87)cc7c5B6c5ccc(-c6ccccc6)cc5O7)c43)c12]

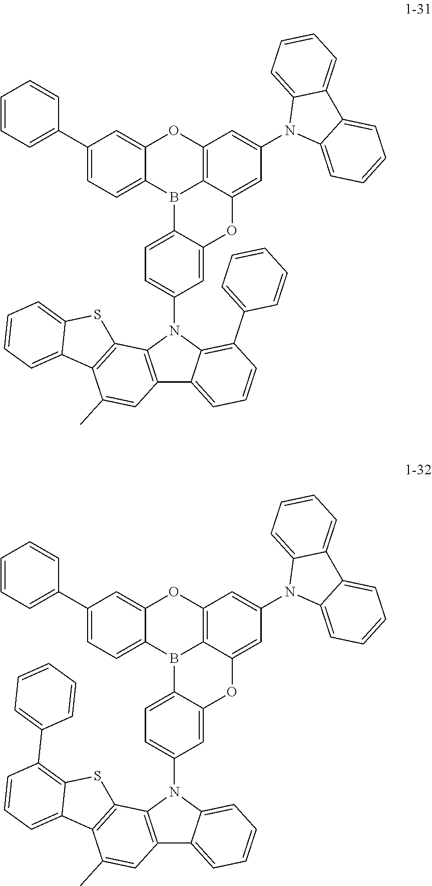 [SMILES: Cc1cc2c3cccc(-c4ccccc4)c3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3c(-c4ccccc4)cccc3c12]

The first compound 342 has beneficial quantum efficiency because the excited triplet exciton can be converted upwardly its excited singlet exciton by RISC mechanism in the first compound 342 of delayed fluorescent material.

In one embodiment, the EML 340 can further comprise the second compound 344 of the host so as to maximize the luminous properties of the first compound 342 of the delayed fluorescent material. As an example, the first compound 342 can have a maximum photoluminescence (PL) wavelength, but is not limited to, between about 400 nm and about 450 nm so as to transfer sufficiently exciton energy from the second compound 344 to the first compound 342.

The second compound 344 that can be comprised in the EML 340 can comprise any organic compound that has wider energy difference Eg between a HOMO energy level and a LUMO energy level compared to the energy difference of the first compound 342. When the EML 340 comprises the second compound 344 of the host, the first compound 342 can be an emitter (dopant).

For example, the second compound 344 can comprise a P-type host with relatively beneficial hole affinity property and/or an N-type host with relatively beneficial electron affinity property. In one embodiment, the P-type host can comprise, but is not limited to, a carbazole-containing organic compound, an aryl amine- or hetero aryl amine-containing organic compound having at least one fused or non-fused aromatic and/or fused or non-fused hetero aromatic moiety and/or an aryl amine- or hetero aryl amine-containing organic compound having a spirofluorene moiety. In one embodiment, the N-type host can comprise, but is not limited to, an azine-containing (e.g., triazine-containing, pyrimidine-containing and/or pyridine-containing) organic compound.

In one embodiment, the second compound 344 of the P-type host can comprise a carbazole-containing organic compound where unsubstituted or substituted carbazole moieties located at both sides of a molecule are linked through plural unsubstituted or substituted phenylene rings. The second compound 344 with such a molecular conformation can comprise an organic compound having the following structure of Chemical Formula 5:

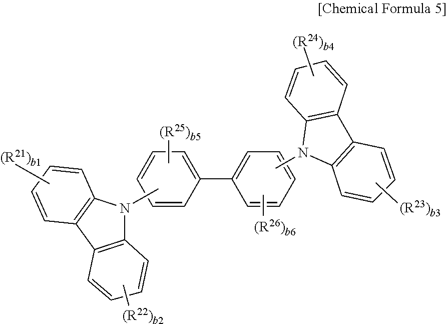

wherein, in Chemical Formulae 5,
each of R²¹, R²², R²³, R²⁴, R²⁵ and R²⁶ is independently a cyano group, an unsubstituted or substituted C₁-C₂₀ alkyl group, an unsubstituted or substituted C₆-C₃₀ aryl group or an unsubstituted or substituted C₃-C₃₀ hetero aryl group, where each R²¹ is identical to or different from each other when b1 is 2, 3 or 4, each R²² is identical to or different from each other when b2 is 2, 3 or 4, each R²³ is identical to or different from each other when b3 is 2, 3 or 4, each R²⁴ is identical to or different from each other when b4 is 2, 3 or 4, each R²⁵ is identical to or different from each other when b5 is 2, 3 or 4, and each R²⁶ is identical to or different from each other when b6 is 2, 3 or 4; and
each of b1, b2, b3, b4, b5 and b6 is independently 0, 1, 2, 3 or 4.

For example, each of R²¹, R²², R²³, R²⁴, R²⁵ and R²⁶ in Chemical Formula 5 can be independently a cyano group, an unsubstituted or substituted C₁-C₁₀ alkyl group (e.g., methyl or tert-butyl) or an unsubstituted or substituted C₆-C₃₀ aryl group (e.g., phenyl unsubstituted or substituted with a C₁-C₁₀ alkyl group such as methyl and/or tert-butyl). In another embodiment, each of b1, b2, b3 and b4 in Chemical Formula 5 can be independently 0 or 1 and/or each of b5 and b6 in Chemical Formula 5 can be independently 0.

More particularly, the second compound 344 having the structure of Chemical Formula 5 can be, but is not limited to, at least one of the following organic compounds of Chemical Formula 6:

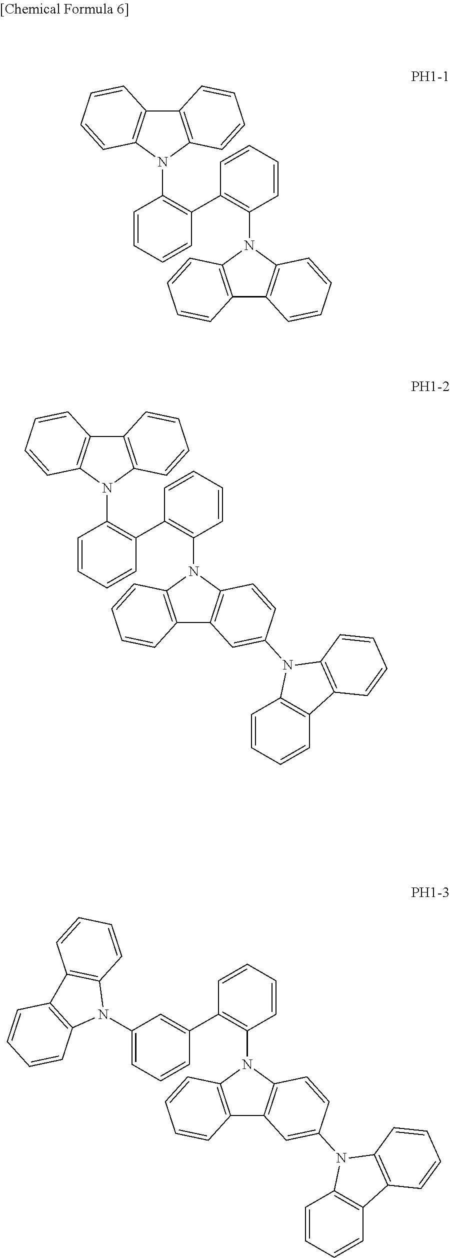 [SMILES: c1ccc(-n2c3ccccc3c3ccccc32)c(-c2ccccc2-n2c3ccccc3c3ccccc32)c1 ; c1ccc(-n2c3ccccc3c3ccccc32)c(-c2ccccc2-n2c3ccccc3c3cc(-n4c5ccccc5c5ccccc54)ccc32)c1 ; c1cc(-c2ccccc2-n2c3ccccc3c3cc(-n4c5ccccc5c5ccccc54)ccc32)cc(-n2c3ccccc3c3ccccc32)c1]

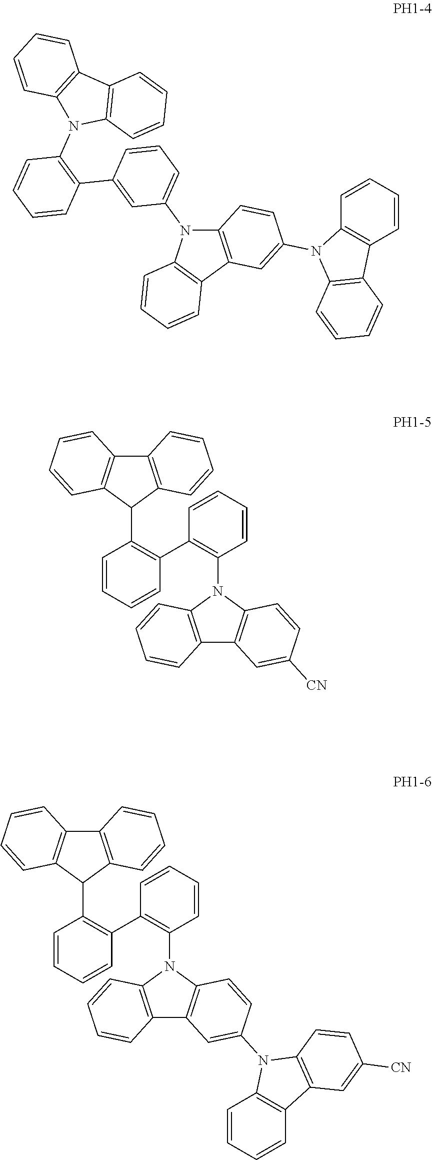 [SMILES: c1cc(-c2ccccc2-n2c3ccccc3c3ccccc32)cc(-n2c3ccccc3c3cc(-n4c5ccccc5c5ccccc54)ccc32)c1 ; N#Cc1ccc2c(c1)c1ccccc1n2-c1ccccc1-c1ccccc1C1c2ccccc2-c2ccccc21 ; N#Cc1ccc2c(c1)c1ccccc1n2-c1ccc2c(c1)c1ccccc1n2-c1ccccc1-c1ccccc1C1c2ccccc2-c2ccccc21]

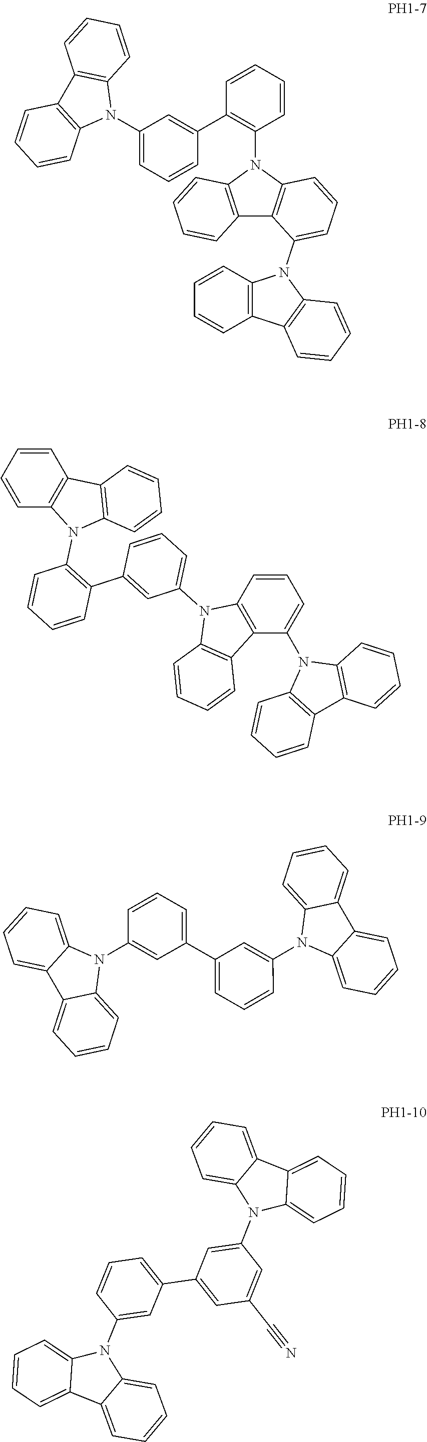 [SMILES: c1cc(-c2ccccc2-n2c3ccccc3c3c(-n4c5ccccc5c5ccccc54)cccc32)cc(-n2c3ccccc3c3ccccc32)c1 ; c1cc(-c2ccccc2-n2c3ccccc3c3ccccc32)cc(-n2c3ccccc3c3c(-n4c5ccccc5c5ccccc54)cccc32)c1 ; c1cc(-c2cccc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3ccccc32)c1]

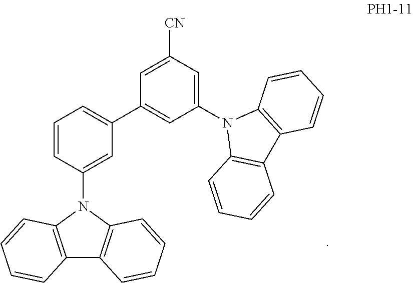 [SMILES: N#Cc1cc(-c2cccc(-n3c4ccccc4c4ccccc43)c2)cc(-n2c3ccccc3c3ccccc32)c1]

In another example embodiment, the second compound 344 of the P-type host can comprise a carbazole-containing organic compound where two carbazole moieties are linked directly to each other and at least one carbazole moiety is substituted. The second compound 344 with such a molecular conformation can have the following structure of Chemical Formula 7:

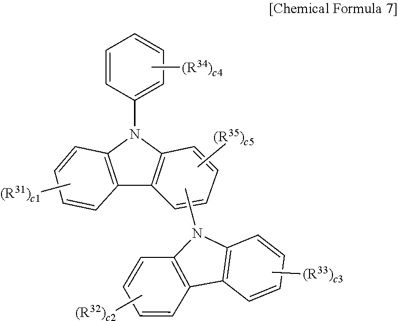

wherein, in Chemical Formula 7,
each of R³¹, R³², R³³, R³⁴ and R³⁵ is independently a cyano group, an unsubstituted or substituted C₁-C₂₀ alkyl group, an unsubstituted or substituted C₆-C₃₀ aryl group or an unsubstituted or substituted C₃-C₃₀ hetero aryl group, an unsubstituted or substituted C₆-C₃₀ triaryl methyl group, an unsubstituted or substituted C₆-C₃₀ triaryl silyl group or an unsubstituted or substituted C₆-C₃₀ triaryl germanyl group, where each R³¹ is identical to or different from each other when c1 is 2, 3 or 4, each R³² is identical to or different from each other when c2 is 2, 3 or 4, each R³³ is identical to or different from each other when c3 is 2, 3 or 4, where each R⁷⁴ is identical to or different from each other when c4 is 2, 3, 4 or 5, and each R³⁵ is identical to or different from each other when c5 is 2 or 3;
each of c1, c2 and c3 is independently 0, 1, 2, 3 or 4;
c4 is 0, 1, 2, 3, 4 or 5; and
c5 is 0, 1, 2 or 3.

For example, each of R³¹, R³², R³³, R³⁴ and R³⁵ in Chemical Formula 7 can be independently an unsubstituted or substituted C₁-C₁₀ alkyl group (e.g., methyl, tert-butyl), an unsubstituted or substituted C₆-C₃₀ aryl group (e.g., phenyl unsubstituted or substituted with C₁-C₁₀ alkyl such as methyl and/or tert-butyl), an unsubstituted or substituted C₃-C₃₀ hetero aryl group (e.g., carbazolyl unsubstituted or substituted with C₁-C₁₀ alkyl such as methyl and/or tert-butyl), an unsubstituted or substituted C₆-C₃₀ triaryl methyl group (e.g., triphenyl methyl), an unsubstituted or substituted C₆-C₃₀ triaryl silyl group (e.g., triphenyl silyl) or an unsubstituted or substituted C₆-C₃₀ triaryl germanyl group (e.g., triphenyl germanyl). In one embodiment, each of c1, c2 and c3 can be independently 0 and/or each of c3 and c4 can be independently 0 or 1 in Chemical Formula 7.

More particularly, the second compound 344 having the structure of Chemical Formula 7 can be, but is not limited to, at least one of the following organic compounds of Chemical Formula 8:

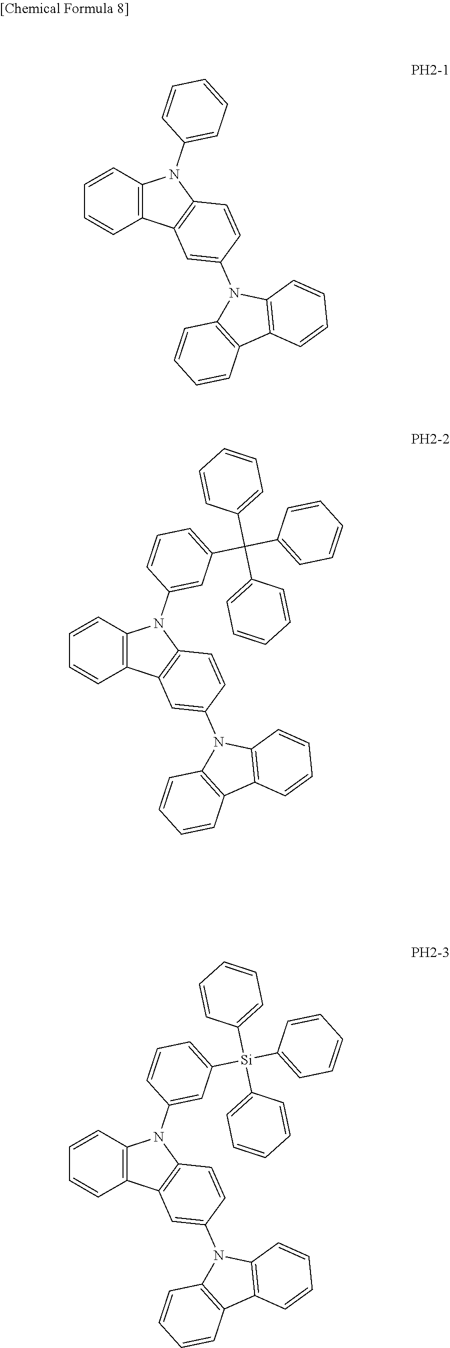 [SMILES: c1ccc(-n2c3ccccc3c3cc(-n4c5ccccc5c5ccccc54)ccc32)cc1 ; c1ccc(C(c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-n3c4ccccc4c4cc(-n5c6ccccc6c6ccccc65)ccc43)c2)cc1]

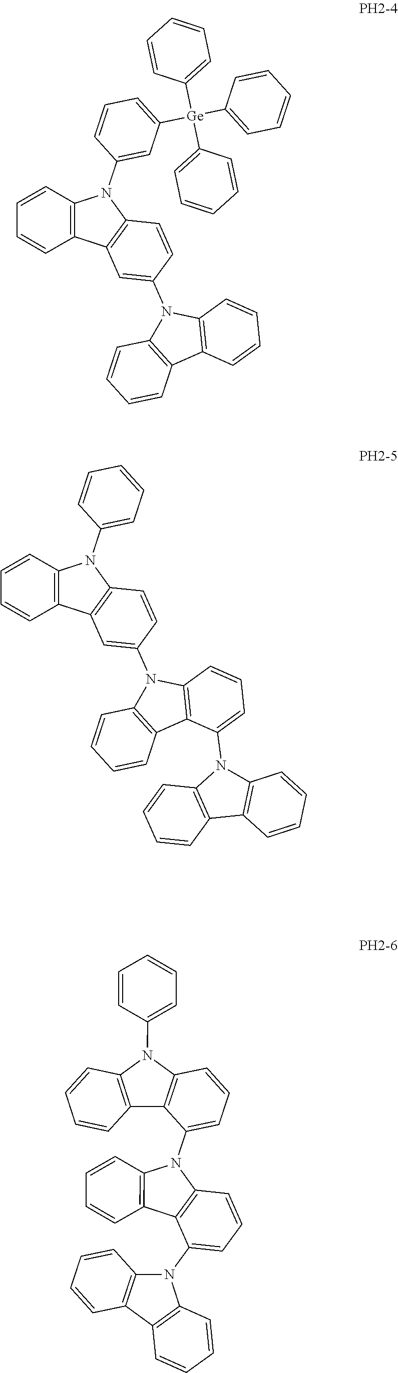

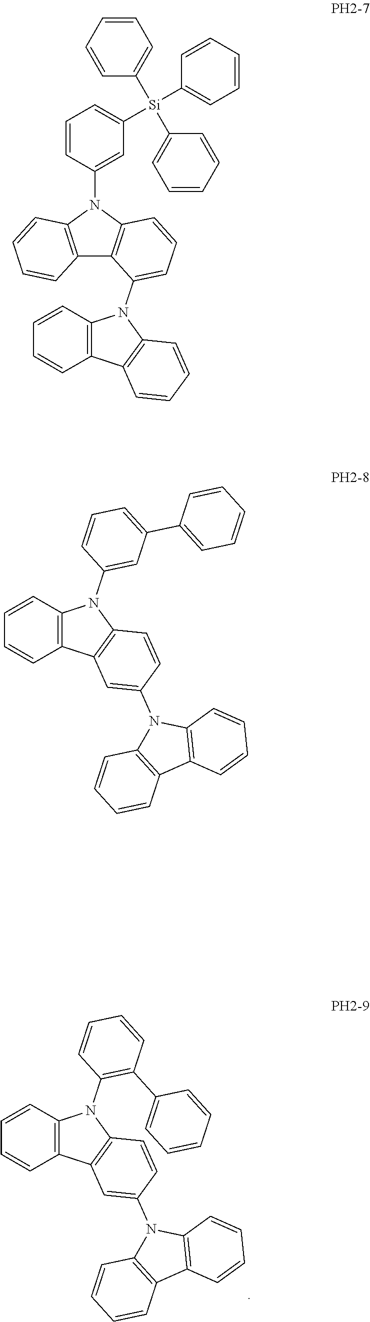 [SMILES: c1ccc([Si](c2ccccc2)(c2ccccc2)c2cccc(-n3c4ccccc4c4c(-n5c6ccccc6c6ccccc65)cccc43)c2)cc1 ; c1ccc(-c2cccc(-n3c4ccccc4c4cc(-n5c6ccccc6c6ccccc65)ccc43)c2)cc1 ; c1ccc(-c2ccccc2-n2c3ccccc3c3cc(-n4c5ccccc5c5ccccc54)ccc32)cc1]

In another embodiment, the second compound 344 can comprise, but is not limited to, 9-(3-(9H-carbazol-9-yl)phenyl)-9H-carbazole-3-carbonitrile (mCP-CN), 4,4′-bis(N-carbazolyl)-1,1′-biphenyl (CBP), 3,3′-bis(N-carbazolyl)-1,1′-biphenyl (mCBP), 1,3-Bis(carbazol-9-yl)benzene (mCP), Bis[2-(diphenylphosphino)phenyl]ether oxide (DPEPO), (oxybis(3-(tert-butyl)-6,1-phenylene))bis(diphenylphosphine oxide) (DPOBBPE), 2,8-bis(diphenylphosphoryl)dibenzothiophene (PPT), 1,3,5-Tri[(3-pyridyl)-phen-3-yl]benzene (TmPyPB), 2,6-Di(9H-carbazol-9-yl)pyridine (PYD-2Cz), 2,8-di(9H-carbazol-9-yl)dibenzothiophene (DCzDBT), 3′,5′-Di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), Diphenyl-4-triphenylsilyl-phenylphosphine oxide (TSPO1), 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-Diphenyl-9H,9′H-3,3′-bicarbazole (BCzPh), 9,9′-Di(4-biphenyl)-9H,9′H-3,3′-bicabazole (BCZ), 1,3,5-Tris(carbazole-9-yl)benzene (TCP), Tris(4-carbazoyl-9-yl-phenyl)amine (TCTA), 4,4′-Bis(carbazole-9-yl)-2,2′-dimethylbiphenyl (CDBP), 2,7-Bis(carbazole-9-yl)-9,9-dimethylfluorene (DMFL-CBP), 2,2′,7,7′-Tetrakis(carbazole-9-yl)-9,9-spirofluorene (Spiro-CBP), 3,6-Bis(carbazole-9-yl)-9-(2-ethyl-hexyl)-9H-carbazole (TCz1), o-CzCN(1), m-CzCN(1), 4CzCzCN, 4CzCNCzCN, 24CzCzCN, 24CzCNCzCN, mBFCzCN, dBFCzCN, m-CzCNDMT, p-CzCNDMT, 2,4-2CzBN, 2,6-2CzBN, 3,5-2CzBN, 3CzBN, CNPhCz, DCNPhCz, o-CzCN, m-CzCN, p-CzCN, oCzBN, mCzBN, pCzBN, CNCzCN1, CNCACN2, CnCzCN3, CnCzCN4, CzDBTCN, DBTCzCN, mCPCz, BPRTZ, MBPRTZ, 3CzFDPhTz, TDPA-TRZ, 3-(4,6-bis(3-(triphenylsilyl)phenyl)-1,3,5-triazine-2-yl)benzonitrile (mSiTrz-mCN, mSiTrZ-oCN, mSiTrz-pCN) and/or combinations thereof.

In one embodiment, when the EML 340 comprises the first compound 342 and the second compound 344, the contents of the second compound 344 in the EML 340 can be larger than the contents of the first compound 342. For example, the contents of the second compound 344 in the EML 340 can be about 50 wt. % to about 99 wt. %, for example, about 55 wt. % to about 90 wt. % or about 60 wt. % to about 80 wt. %, and the contents of first compound 342 in the EML 340 can be about 1 wt. % to about 50 wt. %, for example, about 10 wt. % to about 45 wt. % or about 20 wt. % to about 40 wt. %, but is not limited thereto.

As described above, the first compound 342 has large steric hindrance owing to plural electron donor moieties, and exciton conversions by RISC in the first compound 342 can be occurred rapidly by controlling its HOMO and LUMO energy levels and by maximizing charge transfer efficiency within the molecule. Accordingly, the triplet excitons generated at the first compound 342 can be converted upwardly its singlet excitons by RISC. The first compound 342 can utilize its original singlet excitons as well as the converted singlet excitons converted by RISC so that the first compound 342 can implement 100% internal quantum efficiency. The luminous efficiency in the EML 340 and the OLED D1 including the first compound 342 can be improved.

In addition, it can be necessary to adjust property HOMO energy levels and/or LUMO energy levels of the first compound 342 of delayed fluorescent material and the second compound 344 of host in the EML 340. For example, the second compound 344 of host can induce the triplet excitons in the first compound 342 of delayed fluorescent material to contribute to emission without non-emission, quenching.

For example, the second compound 344 can have a HOMO energy level lower than a HOMO energy level of the first compound 342 and/or can have a LUMO energy level higher than a LUMO energy level of the first compound 342. The energy difference between the HOMO energy level and the LUMO energy level of the second compound 344 can be wider than the energy difference between the HOMO energy level and the LUMO energy level of the first compound 342.

In another embodiment, each of an excited singlet energy level and an excited triplet energy level of the second compound 344 can be higher than an excited singlet energy level and an excited triplet energy level of the first compound 342, respectively. For example, the second compound 344 can have an excited singlet energy level higher than an excited singlet energy level of the first compound 342 by at least about 0.2 eV, for example, at least about 0.3 eV or at least about 0.5 eV.

For example, when the excited singlet energy level and/or the excited triplet energy level of the second compound 344 is not higher sufficiently than the excited singlet energy level and/or the excited triplet energy level of the first compound 342, the singlet and/or triplet excitons generated at the first compound 342 can be transferred reversed to singlet and/or triplet excitons of the second compound 344. The triplet excitons generated at the first compound 342 cannot contribute emission process as the triplet excitons in the second compound 344 are quenched as non-emission because the second compound 344 cannot utilize the triplet excitons. The first compound 342 having delayed fluorescent properties can have energy difference ΔE_{ST} between the excited singlet energy level and the excited triplet energy level of about 0.3 eV or less, for example, between about 0.05 eV and about 0.3 eV.

The HIL 310 is disposed between the first electrode 210 and the HTL 320 and can improve an interface property between the inorganic first electrode 210 and the organic HTL 320. In one embodiment, hole injecting material in the HIL 310 can comprise, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), TCTA, N,N′-Diphenyl-N,N′-bis(1-naphthyl)-1,1′-biphenyl-4,4″-diamine (NPB; NPD), N,N′-Bis{4-[bis(3-methylphenyl)amino]phenyl}-N,N′-diphenyl-4,4′-biphenyldiamine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,2,5,6-Tetrafluoro-7,7,8,8-tetracyanoquinodimethane (F4-TCNQ), 1,3,4,5,7,8-Hexafluoro-tetracyanonapthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB) and/or combinations thereof.

In another embodiment, the HIL 310 can comprise hole transporting material below doped with the hole injecting material (e.g., HAT-CN, F4-TCNQ and/or F6-TCNNQ). For example, the contents of the hole injecting material in the HIL 310 can be about 2 wt. % to about 15 wt. %. In certain embodiments, the HIL 310 can be omitted in compliance of the OLED D1 property.

The HTL 320 is disposed adjacently to the EML 340 between the first electrode 210 and the EML 340. In one embodiment, hole transporting material in the HTL 320 can comprise, but is not limited to, N,N′-Diphenyl-N,N′-bis(3-methylphenyl)-1,1′-biphenyl-4,4′-diamine (TPD), NPB(NPD), DNTPD, CBP, Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))](TFB), Di-[4-(N,N-di-p-tolyl-amino)-phenyl]cyclohexane (TAPC), 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combinations thereof.

The ETL 360 and the EIL 370 can be laminated sequentially between the EML 340 and the second electrode 230. An electron transporting material comprised in the ETL 360 has high electron mobility so as to provide electrons stably to the EML 340 by fast electron transportation.

In one embodiment, the electron transporting material can comprise at least one of an oxadiazole-containing compound, a triazole-containing compound, a phenanthroline-containing compound, a benzoxazole-containing compound, a benzothiazole-containing compound, a benzimidazole-containing compound, a triazine-containing compound and/or combinations thereof.

More particularly, the electron transporting material can comprise, but is not limited to, tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-Tris(N-phenylbenzimidazol-2-yl)benzene (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), TSPO1, 2-[4-(9,10-Di-2-naphthalen2-yl-2-anthracen-2-yl)phenyl]-1-phenyl-1H-benzimidazole (ZADN) and/or combinations thereof:

The EIL 370 is disposed between the second electrode 230 and the ETL 360, and can improve physical properties of the second electrode 230 and therefore, can enhance the lifespan of the OLED D1. In one embodiment, electron injecting material in the EIL 370 can comprise, but is not limited to, an alkali metal halide or an alkaline earth metal halide such as LiF, CsF, NaF, BaF₂ and the like, and/or an organometallic compound such as Liq, lithium benzoate, sodium stearate, and the like.

In another embodiment, the EIL 370 can comprise the electron transporting material doped with alkali metal such as Li, Mg, K and/or combinations thereof and/or alkaline earth metal such as Mg, Ca and/or combinations thereof. In this case, the contents of the alkali metal and/or the alkaline earth metal in the EIL can be, but is not limited to, about 0.5 wt. % to about 10 wt. %.

When holes are transferred to the second electrode 230 via the EML 340 and/or electrons are transferred to the first electrode 210 via the EML 340, the OLED D1 can have short lifespan and reduced luminous efficiency. In order to prevent those phenomena, the OLED D1 in accordance with this aspect of the present disclosure can have at least one exciton blocking layer adjacent to the EML 340.

As an example, the OLED D1 can comprise the EBL 330 between the HTL 320 and the EML 340 so as to control and prevent electron transfers to the HTL 320. In one embodiment, electron blocking material in the EBL 330 can comprise, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof.

In addition, the OLED D1 can further comprise the HBL 350 as a second exciton blocking layer between the EML 340 and the ETL 360 so that holes cannot be transferred from the EML 340 to the ETL 360. In one embodiment, hole blocking material in the HBL 350 can comprise, but is not limited to, at least one of an oxadiazole-containing compound, a triazole-containing compound, a phenanthroline-containing compound, a benzoxazole-containing compound, a benzothiazole-containing compound, a benzimidazole-containing compound, a triazine-containing compound and/or combinations thereof.

For example, the hole blocking material in the HBL 350 can comprise material having a relatively low HOMO energy level compared to the luminescent materials in EML 340. The hole blocking material can comprise, but is not limited to, BCP, BAlq, Alq₃, PBD, spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof.

In FIG. 3, the first compound 342 and the second compound 344 are applied into the EML 340 within the emissive layer 220 having a single emitting part. Alternatively, an organic light emitting diode can comprise two or more emitting parts. FIG. 4 illustrates a cross-sectional view of an organic light emitting diode having a two emitting parts in accordance with another embodiment of the present disclosure.

As illustrated in FIG. 4, the organic light emitting diode (OLED) D2 comprises a first electrode 210, a second electrode 230 facing the first electrode 210 and an emissive layer 220A disposed between the first and second electrodes 210 and 230. The organic light emitting display device 100 comprises a red pixel region, a green pixel region and a blue pixel region, and the OLED D1 can be disposed in the red pixel region, the green pixel region and the blue pixel region.

As an example, the OLED D2 can be disposed in the blue pixel region. The first electrode 210 can be an anode and the second electrode 230 can be a cathode, but is not limited thereto.

The emissive layer 220A comprises a first emitting part 300 and a second emitting part 400.

The emissive layer 200A can further comprise a charge generation layer (CGL) 380 disposed between the first emitting part 300 and the second emitting part 400 so that the first emitting part 300, the CGL 380 and the second emitting part 400 are stacked sequentially between the first electrode 210 and the second electrode 230. In other words, the first emitting part 300 is disposed between the first electrode 210 and the CGL 380, and the second emitting part 400 is disposed between the CGL 380 and the second electrode 230.

The first emitting part 300 comprises a first emitting material layer (lower emitting material layer, EML1) 340. The first emitting part 300 can further comprise at least one of a hole injection layer (HIL) 310 disposed between the first electrode 210 and the EML1 340, a first hole transport layer (HTL1) 320 disposed between the HIL 310 and the EML1 340 and a first electron transport layer (ETL1) 360 disposed between the EML1 340 and the CGL 380. Alternatively, the first emitting part 300 can further comprise at least one of a first electron blocking layer (EBL1) 330 disposed between the HTL1 320 and the EML1 340 and a first hole blocking layer (HBL1) 350 disposed between the EML1 340 and the ETL1 360.

The second emitting part 400 comprises a second emitting material layer (upper emitting material layer, EML2) 440. The second emitting part 400 can further comprise at least one of a second hole transport layer (HTL2) 420 disposed between the CGL 380 and the EML2 440, a second electron transport layer (ETL2) 460 disposed between the EML2 440 and the second electrode 230 and an electron injection layer (EIL) 470 disposed between the ETL2 460 and the second electrode 230. Alternatively, the second emitting part 400 can further comprise at least one of a second electron blocking layer (EBL2) 430 disposed between the HTL2 420 and the EML2 440 and a second hole blocking layer (HBL2) 450 disposed between the EML2 440 and the ETL2 460.

The materials of the HIL 310, the HTL1 320 and the HTL2 420, the EBL1 330 and the EBL2 430, the HBL1 350 and the HBL2 450, the ETL1 360 and the ETL2 460 and the EIL 470 can be identical to the corresponding materials with referring to FIG. 3.

The CGL 380 disposed between the first emitting part 300 and the second emitting part 400. The first emitting part 300 and the second emitting part 400 are connected by the CGL 380. The CGL 380 can be PN-junction charge generation layer in which an N-type charge generation layer (N-CGL) 382 and a P-type charge generation layer (P-CGL) 384 are connected.

The N-CGL 382 is disposed between the ETL1 360 and the HTL2 420 and the P-CGL 384 is disposed between the N-CGL 382 and the HTL2 420. The N-CGL 382 provides electrons to the EML1 340 of the first emitting part 300 and the P-CGL 384 provides holes to the EML2 440 of the second emitting part 400.

For example, the N-CGL 382 can comprise electron transporting material doped with an alkali metal (e.g., Li, Na, K, Rb and Cs) and/or an alkaline earth metal (e.g., Mg, Ca, Sr, Ba and Ra). The contents of the alkali metal and/or the alkaline earth metal in the N-CGL 382 can be, but is not limited to, between about 1 wt. % and about 10 wt. %. As an example, the P-CGL 384 can comprise hole transporting material doped with hole injecting material (e.g., HAT-CN, F4-TCNQ and/or F6-TCNNQ). The contents of the hole injecting material in the P-CGL 384 can be, but is not limited to, about 2 wt. % to about 15 wt. %.

In one embodiment, both the EML1 340 and the EML2 440 can be a blue emitting material layer. For example, the EML1 340 comprises a first compound 342 having the structure of Chemical Formulae 1, 2 and 4 of delayed fluorescent material, and optionally, a second compound 344 of a host. Also, the EML2 440 comprises a first compound 442 having the structure of Chemical Formulae 1, 2 and 4 of delayed fluorescent material, and optionally, a second compound 444 of a host.

Each of the first compound 342 and the second compound 344 in the EML1 340 can be independently identical to or different from the first compound 442 and the second compound 444 in the EML2 440, respectively. The contents of the luminous materials in each of the EML1 340 and the EML2 440 can be identical to the contents of the corresponding materials with referring to FIG. 3

Alternatively, the EML2 440 comprise materials different from at least one of the first compound 342 and the second compound 344 in the EML1 340 so that the EML2 440 can emit color different from the EML1 340 or can have luminous efficiency different from the EML1 340.

The EML2 440 as well as the EML1 340 in the OLED D2 comprises the first compound 342 or 442 of delayed fluorescent material so that the OLED can have beneficial luminous efficiency. In addition, the OLED D2 can have beneficial color sense and optimized luminous efficiency since the OLED D2 has a dual stack structure of two emitting material layers.

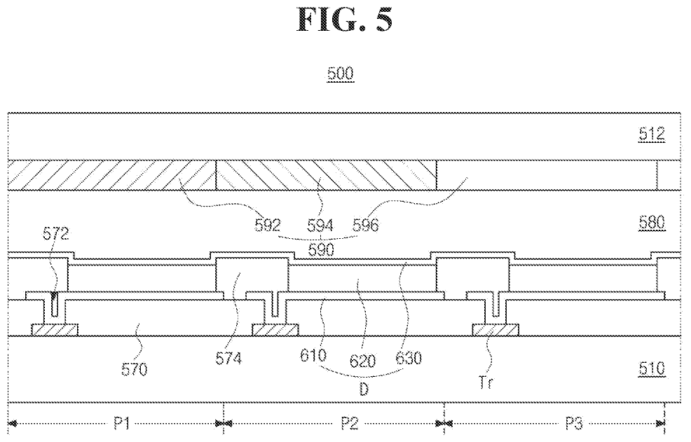

OLED D1 with a single emitting part and the OLED D2 with two emitting parts are shown in FIGS. 3 to 4. In another embodiment, an organic light emitting display device can implement full-color including white color. FIG. 5 illustrates a schematic cross-sectional view of an organic light emitting display device in accordance with another embodiment of the present disclosure.

As illustrated in FIG. 5, the organic light emitting display device 500 comprises a first substrate 510 that defines each of a first pixel region P1, a second pixel region P2 and a third pixel region P3, a second substrate 512 facing the first substrate 510, a thin film transistor Tr on the first substrate 510, an OLED D disposed between the first and second substrates 510 and 512 and emitting white (W) light and a color filter layer 590 disposed between the OLED D and the second substrate 512. For example, each of the first to third pixel regions P1, P2 and P3 can be a red pixel region, a green pixel region and a blue pixel region, respectively. Alternatively, the first substrate 510 can further comprise a fourth pixel region of a white pixel region. The organic light emitting display device 500 can comprise a plurality of such pixel regions arranged in a matrix configuration or other suitable configurations.

Each of the first and second substrates 510 and 512 can comprise, but is not limited to, glass, flexible material and/or polymer plastics. For example, each of the first and second substrates 510 and 512 can be made of PI, PES, PEN, PET, PC and/or combinations thereof. In certain embodiments, the second substrate 512 can be omitted. The first substrate 510, on which a thin film transistor Tr and the OLED D are arranged, forms an array substrate. In certain embodiments, the second substrate 512 can be omitted.

The thin film transistor Tr can be disposed on the first substrate 510. Alternatively, a buffer layer is disposed on the first substrate 510 and the thin film transistor Tr can be disposed on the buffer layer. As illustrated in FIG. 2, the thin film transistor can comprise a semiconductor layer, a gate electrode, a source electrode and a drain electrode and acts as a driving element.

In some aspects, as shown in FIG. 1, the gate line GL and the data line DL, which cross each other to define the pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL, and the thin film transistor Tr can further comprise the storage capacitor Cst configured to constantly keep a voltage of the gate electrode 140 for one frame.

A passivation layer 570 is disposed on the thin film transistor Tr. The passivation layer 570 has a flat top surface and has a drain contact hole 572 that exposes or does not cover the drain electrode of the thin film transistor Tr.

The OLED D is located on the passivation layer 570 correspondingly to the color filter layer 590. The OLED D comprises a first electrode 610 that is connected to the drain electrode of the thin film transistor Tr, and an emissive layer 620 and a second electrode 630 disposed sequentially on the first electrode 610. The OLED D emits white color light in the first to third pixel regions P1, P2 and P3.

The first electrode 610 is formed for each pixel region P1, P2 or P3 and the second electrode 630 is formed integrally corresponding to the first to third pixel regions P1, P2 and P3. The first electrode 610 can be one of an anode and a cathode and the second electrode 630 can be the other of the anode and the cathode. In one embodiment, the first electrode 610 can be a reflective electrode and the second electrode 630 can be a transmissive (or semi-transmissive) electrode. Alternatively, the first electrode 610 can be the transmissive (or semi-transmissive) electrode and the second electrode 630 can be the reflective electrode.

For example, the first electrode 610 can be the anode, and can comprise a conductive material having relatively high work function value, for example, transparent conductive oxide (TCO). As an example, the first electrode 610 can comprise, but is not limited to, ITO, IZO, ITZO, SnO, ZnO, ICO, AZO, and/or combinations thereof. Alternatively, a reflective electrode or a reflective layer can be disposed under the first electrode 610.

The second electrode 630 can be the cathode, and can comprise a conductive material having relatively low work function value, for example, low resistant metal. For example, the second electrode 630 can comprise, but is not limited to, Al, Mg, Ca, Ag, alloy thereof (e.g., Mg—Al alloy) and/or combinations thereof.

In one embodiment, as the light emitted from the emissive layer 620 can be incident to the color filter layer 590 through the second electrode 630 in the organic light emitting display device 500, the second electrode 630 can have a thin thickness to transmit the light emitted from the emissive layer 620.

An emissive layer 620 can comprise at least two emitting parts each of which emits different color light. Each emitting part can have single-layered structure of an emitting material layer (EML). Alternatively, each emitting part can further comprise at least one of a hole injection layer (HIL), a hole transport layer (HTL), an electron blocking layer (EBL), a hole blocking layer (HBL), an electron transport layer (ETL) and an electron injection layer (EIL). In addition, the emissive layer 620 can further comprise at least one charge generation layer (CGL) disposed between two emitting parts.

A bank layer 574 is disposed on the passivation layer 570 in order to cover edges of the first electrode 610. The bank layer 574 exposes or does not cover a center of the first electrode 610 corresponding to each of the first to third pixel regions P1, P2 and P3. The bank layer 574 is formed to prevent current leakage at the edge of the first electrode 610. In certain embodiments, the bank layer 574 can be omitted.

Since the OLED D emits white color light in the first to third pixel regions P1, P2 and P3, the emissive layer 620 can be formed as a common layer without being separated from in the first to third pixel regions P1, P2 and P3.

The organic light emitting display device 500 can further comprise an encapsulation film 580 that can be disposed on the second electrode 630 in order to prevent or reduce outer moisture from penetrating into the OLED D. In addition, a polarizing plate can be attached under the first substrate 510 or onto the second substrate 512 to reduce reflection of external light.

The color filter layer 590 is disposed on the OLED D or the encapsulation film 580. For example, the color filter layer 590 can comprise a first color filter layer 592 corresponding to the first pixel region P1, a second color filter layer 594 corresponding to the second pixel region P2 and a third color filter layer 596 corresponding to the third pixel region P3. For example, the first color filter layer 592 can be a red color filter layer, the second color filter layer 594 can be a green color filter layer and the third color filter layer 596 can be a blue color filter layer.

For example, the first color filter layer 592 can comprise at least one of red dye and blue pigment, the second color filter layer 594 can comprise at least one of green dye and green pigment and the third color filter layer 596 can comprise at least one of blue dye and blue pigment. In one embodiment, the color filter layer 590 can be attached to the OLED D through an adhesive layer. Alternatively, the color filter layer 590 can be disposed directly on the OLED D.

In FIG. 5, the light emitted from the OLED D is transmitted through the second electrode 630 and the color filter layer 590 is disposed on the OLED D. In this case, the organic light emitting display device 500 can be a top-emission type. Alternatively, when the organic light emitting display device 500 is a bottom-emission type, the light emitted from the OLED D is transmitted through the first electrode 610 and the color filter layer 590 can be disposed between the OLED D and the first substrate 510.

In addition, a color conversion layer can be formed or disposed between the OLED D and the color filter layer 590. The color conversion layer can comprise a red color conversion layer, a green color conversion layer and a blue color conversion layer each of which is disposed correspondingly to each pixel region P1, P2 or P3, so as to convert the white (W) color light to each of a red, green and blue color lights, respectively. Alternatively, the organic light emitting display device 500 can comprise the color conversion layer instead of the color filter layer 590.

As described above, the white (W) color light emitted from the OLED D is transmitted through the first to third color filter layers 592, 594 and 596 each of which is disposed correspondingly to the first to third pixel regions P1, P2 and P3, respectively, so that red, green and blue color lights are displayed in the first to third pixel regions P1, P2 and P3.

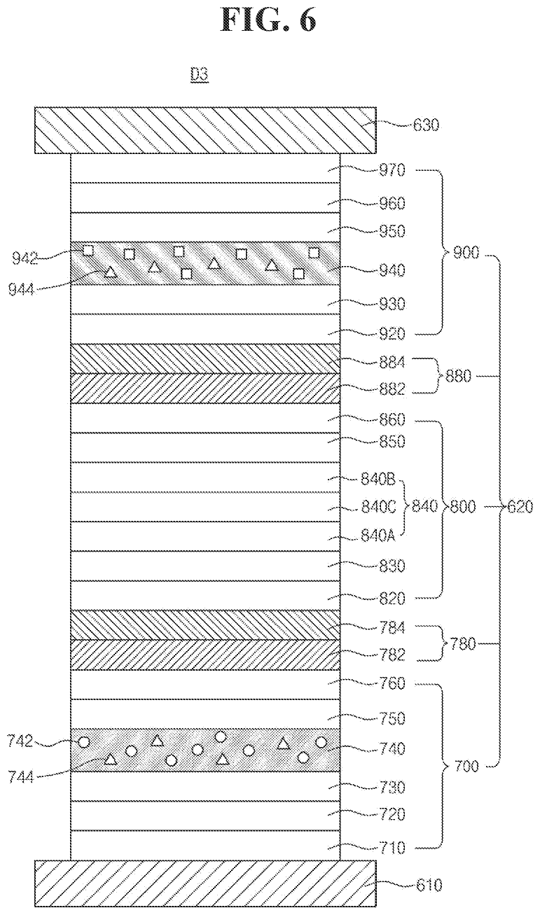

An OLED that can be applied into the organic light emitting display device will now be described in more detail. An example of the OLED D of FIG. 5 is shown in FIG. 6 as an OLED D3. Particularly, FIG. 6 illustrates a schematic cross-sectional view of an organic light emitting diode having a tandem structure of three emitting parts.

As illustrated in FIG. 6, the OLED D3 in accordance with the embodiment of the present disclosure comprises first and second electrodes 610 and 630 facing each other and an emissive layer 620 disposed between the first and second electrodes 610 and 630. The emissive layer 620 comprises a first emitting part 700 disposed between the first electrode 610 and the second electrode 630, a second emitting part 800 disposed between the first emitting part 700 and the second electrode 630, a third emitting part 900 disposed between the second emitting part 800 and the second electrode 630, a first charge generation layer (CGL1) 780 disposed between the first emitting part 700 and the second emitting part 800, and a second charge generation layer (CGL2) 880 disposed between the second emitting part 800 and the third emitting part 900.

The first emitting part 700 comprises a first emitting material layer (lower emitting material layer, EML1) 740. The first emitting part 700 can further comprise at least one of a hole injection layer (HIL) 710 disposed between the first electrode 610 and the EML1 740, a first hole transport layer (HTL1) 720 disposed between the HIL 710 and the EML1 740, and a first electron transport layer (ETL1) 760 disposed between the EML1 740 and the CGL1 780. Alternatively, the first emitting part 700 can further comprise at least one of a first electron blocking layer (EBL1) 730 disposed between the HTL1 720 and the EML1 740 and a first hole blocking layer (HBL1) 750 disposed between the EML1 740 and the ETL 760.

The second emitting part 800 comprises a second emitting material layer (middle emitting material layer, EML2) 840. The second emitting part 800 can further comprise at least one of a second hole transport layer (HTL2) 820 disposed between the CGL1 780 and the EML2 840 and a second electron transport layer (ETL2) 860 disposed between the EML2 840 and the CGL2 880. Alternatively, the second emitting part 800 can further comprise at least one of a second electron blocking layer (EBL2) 830 disposed between the HTL2 820 and the EML2 840 and a second hole blocking layer (HBL2) 850 disposed between the EML2 840 and the ETL2 860.

The third emitting part 900 comprises a third emitting material layer (upper emitting material layer, EML3) 940. The third emitting part 900 can further comprise at least one of a third hole transport layer (HTL3) 920 disposed between the CGL2 880 and the EML3 940, a third electron transport layer (ETL3) 960 disposed between the EML3 940 and the second electrode 630, an electron injection layer (EIL) 970 disposed between ETL3 960 and the second electrode 630. Alternatively, the third emitting part 900 can further comprise a third electron blocking layer (EBL3) 930 disposed between the HTL3 920 and the EML3 940 and a third hole blocking layer (HBL3) 950 disposed between the EML3 940 and the ETL3 960.

The CGL1 780 is disposed between the first emitting part 700 and the second emitting part 800 and the CGL2 880 is disposed between the second emitting part 800 and the third emitting part 900. The CGL1 780 comprises a first N-type charge generation layer (N-CGL1) 782 disposed between the ETL1 760 and the HTL2 820 and a first P-type charge generation layer (P-CGL1) 784 disposed between the N-CGL1 782 and the HTL2 820. The CGL2 880 comprises a second N-type charge generation layer (N-CGL2) 882 disposed between the ETL2 860 and the HTL3 920 and a second P-type charge generation layer (P-CGL2) 884 disposed between the N-CGL2 882 and the HTL3 920.

Each of the N-CGL1 782 and the N-CGL2 882 provides electrons to the EML1 740 of the first emitting part 700 and the EML2 840 of the second emitting part 800, respectively. Each of the P-CGL1 784 and the P-CGL2 884 provides holes to the EML2 840 of the second emitting part 800 and the EML3 940 of the third emitting part 900, respectively.

The materials of the HIL 710, the HTL1 to HTL3 720, 820 and 920, the EBL1 to EBL3 730, 830 and 930, the HBL1 to HBL3 750, 850 and 950, the ETL1 to ETL3 760, 860 and 960, the EIL 970, the CGL1 780 and the CGL2 880 can be identical to the corresponding materials with referring to FIGS. 3 and 4.

At least one of the EML1 740, the EML2 840 and the EML3 940 can comprise a first compound, and optionally, a second compound to emit blue color light. For example, at least one of the EML1 740, the EML2 840 and the EML3 940 can emit blue color light and the other of the EML1 740, the EML2 840 and the EML3 940 can emit red to green color light, so that the OLED D3 can realize white (W) emission. Hereinafter, the OLED D3 where the EML1 740 and/or the EML3 940 comprise the organic compound having the structure of Chemical Formulae 1, 2 and 4 to 8 to emit blue color light, and the EML2 840 emits red to green color light will be described in detail.

In one embodiment, each of the EML1 740 and the EML3 940 can be a blue emitting material layer. For example, the EML1 740 can comprise a first compound 742 having the structure of Chemical Formulae 1, 2 and 4 of delayed fluorescent material, and optionally, a second compound 744 of a host. Also, the EML3 940 comprises a first compound 942 having the structure of Chemical Formulae 1, 2 and 4 of delayed fluorescent material, and optionally, a second compound 944 of a host.

Each of the first compound 742 and the second compound 744 in the EML1 740 can be independently identical to or different from the first compound 942 and the second compound 944 in the EML3 940, respectively. The contents of the luminous materials in each of the EML1 740 and the EML3 940 can be identical to the contents of the corresponding materials with referring to FIGS. 3 and 4.

Alternatively, the EML3 940 comprise materials different from at least one of the first compound 742 and the second compound 744 in the EML1 740 so that the EML3 940 can emit color different from the EML1 740 or can have luminous efficiency different from the EML1 740.

The EML2 840 can comprise a first layer 840A disposed between the EBL2 830 and the HBL2 850, a second layer 840B disposed between the first layer 840A and the HBL2 850, and optionally, a third layer 840C disposed between the first layer 840A and the second layer 840B. In one embodiment, one of the first layer 840A and the second layer 840B can emit red color light and the other of the first layer 840A and the second layer 840B can emit green color light. Hereinafter, the EML2 840 where the first layer 840A emits a red color light and the second layer 840B emits a green color light will be described in detail.

The first layer 840A comprises a red host and a red emitter (red dopant). As an example, the red host can comprise at least one of a P-type red host and an N-type red host. The second layer 840B comprises a green host and a green emitter (green dopant). As an example, the green host can comprise at least one of a P-type green host and an N-type green host. The third layer 840C comprises a yellow-green host and a yellow-green emitter (yellow-green dopant). As an example, the yellow-green host can comprise at least one of a P-type yellow-green host and an N-type yellow-green host.

In one embodiment, each of the P-type red host, the P-type green host and the P-type yellow-green host can independently comprise, but is not limited to, at least one of a carbazole-containing organic compound, an aryl amine- or hetero aryl amine-containing organic compound and a spirofluorene-containing organic compound. In another embodiment, each of the N-type red host, the N-type green host and the N-type yellow-green host can independently comprise, but is not limited to, at least one of an azine-containing organic compound and a quinazoline-containing organic compound.

For example, each of the red host, the green host and the yellow-green host can independently comprise, but is not limited to, mCP-CN, CBP, mCBP, mCP, DPEPO, PPT, TmPyPB, PYD-2Cz, DCzDBT, DCzTPA, pCzB-2CN, mCzB-2CN, TSPO1, CCP, 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, BCzPh, BCZ, TCP, TCTA, CDBP, DMFL-CBP, Spiro-CBP, TCz1, BPBPA, TBPi and/or combinations thereof.

The red emitter can comprise at least one of red phosphorescent material, red fluorescent material and red delayed fluorescent material. As an example, the red emitter can comprise, but is not limited to, Bis[2-(4,6-dimethyl)phenylquinoline)](2,2,6,6-tetramethylheptane-3,5-dionate)iridium(III), Bis[2-(4-n-hexylphenyl)quinoline](acetylacetonate)iridium(III) (Hex-Ir(phq)₂(acac)), Tris[2-(4-n-hexylphenyl)quinoline]iridium(III) (Hex-Ir(phq)₃), Tris[2-phenyl-4-methylquinoline]iridium(III) (Ir(Mphq)₃), Bis((2-phenylquinoline)(2,2,6,6-tetramethylheptene-3,5-dionate)iridium(III) (Ir(dpm)PQ₂), Bis(phenylisoquinoline)(2,2,6,6-tetramethylheptene-3,5-dionate)iridium(III) (Ir(dpm)(piq)₂), Bis(1-phenylisoquinoline)(acetylacetonate)iridium(III) (Ir(piq)₂(acac)), Bis[(4-n-hexylphenyl)isoquinoline](acetylacetonate)iridium(II) (Hex-Ir(piq)₂(acac)), Tris[2-(4-n-hexylphenyl)quinoline]iridium(III) (Hex-Ir(piq)₃), Tris(2-(3-methylphenyl)-7-methyl-quinolato)iridium (Ir(dmpq)₃), Bis[2-(2-methylphenyl)-7-methylquinoline](acetylacetonate)iridium(III) (Ir(dmpq)₂(acac)), Bis[2-(3,5-dimethylphenyl)-4-methylquinoline](acetylacetonate)iridium(III) (Ir(mphmq)₂(acac)), Tris(dibenzoylmethane)mono(1,10-phenanthroline)europium(III) (Eu(dbm)₃(phen)) and/or combinations thereof.

For example, the contents of the red host in the first layer 840A can be about 50 wt. % to about 99 wt. %, for example, about 80 wt. % to about 95 wt. %, and the contents of the red emitter in the first layer 840A can be about 1 wt. % to about 50 wt. %, for example, about 5 wt. % to about 20 wt. %, but is not limited thereto. When the first layer 840A comprises both the P-type red host and the N-type red host, the P-type red host and the N-type red host can be admixed, but is not limited to, with a weight ratio of about 4:1 to about 1:4, for example about 3:1 to about 1:3.

The green emitter can comprise at least one of green phosphorescent material, green fluorescent material and green delayed fluorescent material. As an example, the green emitter can comprise, but is not limited to, [Bis(2-phenylpyridine)](pyridyl-2-benzofuro[2,3-b]pyridine)iridium, Tris[2-phenylpyridine]iridium(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tris[2-(p-tolyl)pyridine]iridium(III) (Ir(mppy)₃), Bis(2-(naphthalene-2-yl)pyridine)(acetylacetonate)iridium(III) (Ir(ppy)₂acac), Tris(2-phenyl-3-methyl-pyridine)iridium (Ir(3mppy)₃), fac-Tris(2-(3-p-xylyl)phenyl)pyridine iridium(III) (TEG) and/or combinations thereof.

The contents of the green host in the second layer 840B can be about 50 wt. % to about 99 wt. %, for example, about 80 wt. % to about 95 wt. %, and the contents of the green emitter in the second layer 840B can be about 1 wt. % to about 50 wt. %, for example, about 5 wt. % to about 20 wt. %, but is not limited thereto. When the second layer 840B comprises both the P-type green host and the N-type green host, the P-type green host and the N-type green host can be admixed, but is not limited to, with a weight ratio of about 4:1 to about 1:4, for example about 3:1 to about 1:3.

The yellow-green emitter can comprise at least one of yellow-green phosphorescent material, yellow-green fluorescent material and yellow-green delayed fluorescent material. For example, the yellow-green emitter can comprise, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)iridium(III) (Ir(BT)₂(acac)), Bis(2-(9,9-diethyl-fluoren-2-yl)-1-phenyl-1H-benzo[d]imidazolate)(acetylacetonate)iridium(III) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline)(picolinate)iridium(III) (FPQIrpic), Bis(4-phenylthieno[3,2-c]pyridinato-N,C2′) (acetylacetonate) iridium(III) (PO-01) and/or combinations thereof.

The contents of the yellow-green host in the third layer 840C can be about 50 wt. % to about 99 wt. %, for example, about 80 wt. % to about 95 wt. %, and the contents of the yellow-green emitter in the third layer 840C can be about 1 wt. % to about 50 wt. %, for example, about 5 wt. % to about 20 wt. %, but is not limited thereto. When the third layer 840C comprises both the P-type yellow-green host and the N-type yellow-green host, the P-type yellow-green host and the N-type yellow-green host can be admixed, but is not limited to, with a weight ratio of about 4:1 to about 1:4, for example about 3:1 to about 1:3.

In FIG. 6, the OLED D3 has three emitting parts, but the OLED can have two emitting parts by omitting the third emitting part 900 and the CGL2 880.

The OLED D3 has a tandem structure and comprises the first compound 742 or 942 having the structure of Chemical Formulae 1, 2 and 4 which has beneficial luminous properties owing to its enhanced delayed fluorescent property, and optionally, the second compound 744 or 944 having the structure of Chemical Formulae 5 to 8 of the host. Since the OLED D3 comprises the first compound 742 or 942 of delayed fluorescent material, the luminous efficiency and/or color purity of the OLED D3 can be improved. In addition, the OLED D3 comprises multiply stacked emitting parts so that the white emission with beneficial luminous property and luminous lifetime can be realized.

### Example 1 (Ex. 1): Fabrication of OLED

An organic light emitting diode where an emitting material layer comprises Compound 1-1 (ΔE_{ST}: 0.13 eV, PLₘₐₓ: 449 nm) in Chemical Formula 4 of a first compound and mCBP (HOMO: −6.0 eV, LUMO: −2.4 eV) of a second compound. A glass substrate onto which ITO (50 nm) was coated as a thin film was washed with UV ozone and transferred to a vacuum chamber for depositing emissive layer. Subsequently, an emissive layer and a cathode were deposited by evaporation from a heating boat under about 5-7×10⁻⁷ Torr with setting a deposition rate 1 Å/s as the following order:

A hole injection layer (HIL, HAT-CN, 10 nm); a hole transport layer (HTL, NPB, 40 nm); an electron blocking layer (EBL, TAPC, 10 nm); an emitting material layer (EML, mCBP 70 wt. %, Compound 1-1 30 wt. %, 30 nm); a hole blocking layer (HBL, B3PYMPM, 10 nm); an electron transport layer (ETL, TPBi, 30 nm); electron injection layer (EIL, LiF, 70 nm); and cathode (Al, 70 nm).

The structures of materials of hole injecting material, hole transporting material, electron blocking material, mCBP, hole blocking material and electron transporting material are illustrated in the following:

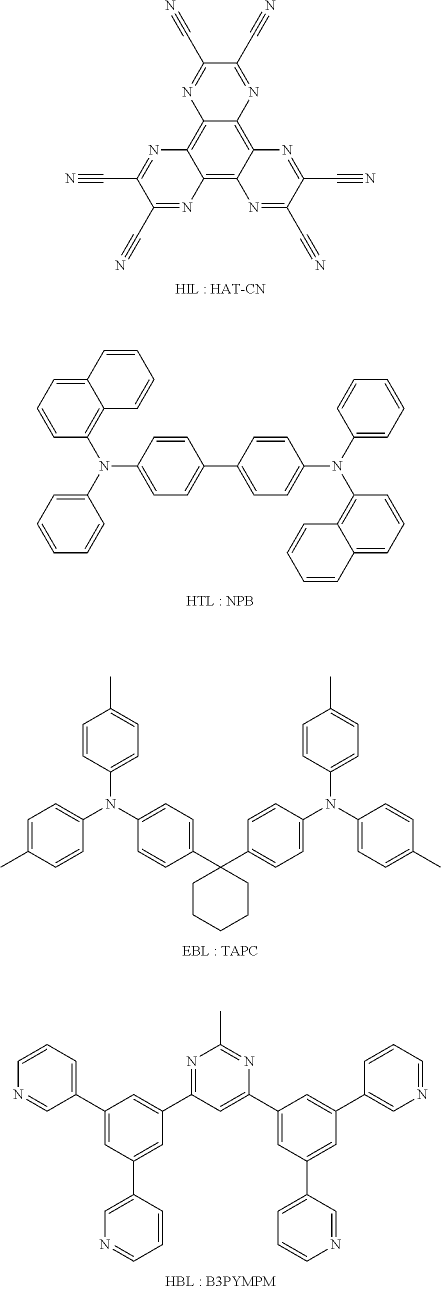

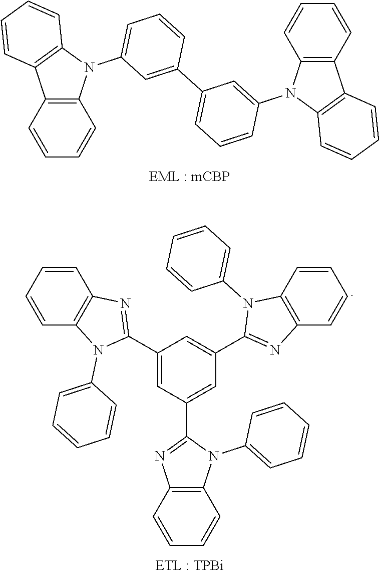 [SMILES: c1cc(-c2cccc(-n3c4ccccc4c4ccccc43)c2)cc(-n2c3ccccc3c3ccccc32)c1 ; c1ccc(-n2c(-c3cc(-c4nc5ccccc5n4-c4ccccc4)cc(-c4nc5ccccc5n4-c4ccccc4)c3)nc3ccccc32)cc1]

### Example 2 (Ex. 2): Fabrication of OLED

An OLED was fabricated using the same procedure and the same materials as Example 1, except that Compound 1-2 (ΔE_{ST}: 0.12 eV, PLₘₐₓ: 443 nm) in Chemical Formula 4 instead of Compound 1-1 as the first compound was used in the EML.

### Comparative Examples 1-3 (Ref. 1-3): Fabrication of OLED

An OLED was fabricated using the same procedure and the same materials as Example 1, except that Compound Ref. 1 (Ref. 1), Compound Ref. 2 (Ref. 2) or Compound Ref. 3 (Ref. 3) instead of Compound 1-1 as the first compound was used in the EML.

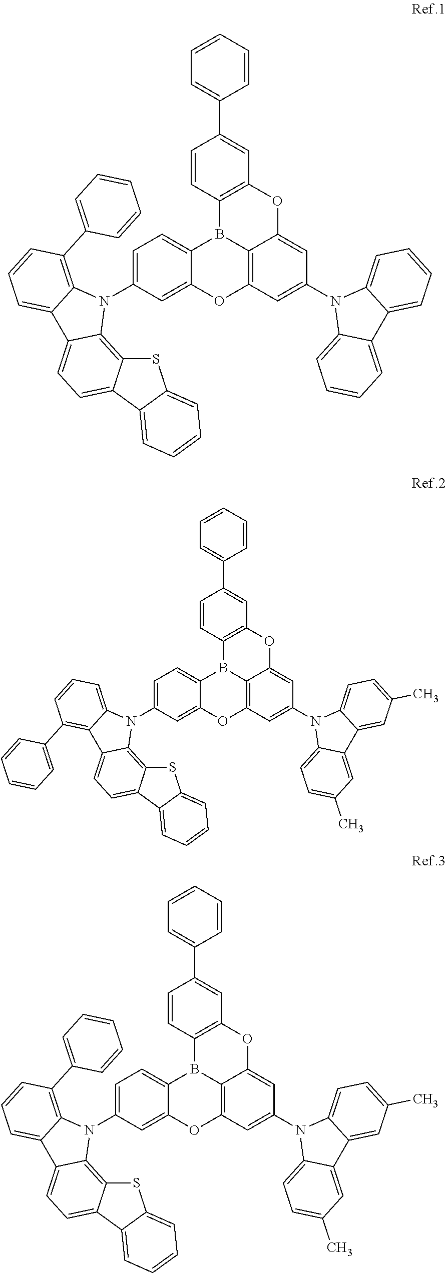

### Experimental Example 1: Measurement of Luminous Properties of OLEDs

Each of the OLEDs, having 9 mm² of emission area, fabricated in Examples 1 to 2 and Comparative Examples 1 to 3 was connected to an external power source and then luminous properties for all the OLEDs were evaluated using a constant current source (KEITHLEY) and a photometer PR650 at room temperature. In particular, driving voltage (V), EQE, maximum electroluminescence wavelength (EL λₘₐₓ, nm) and FWHM (nm) were measured at a current density 8.6 mA/cm². The measurement results are illustrated in the following Table 1.

TABLE 1
Luminous Properties of OLED

| Sample | V | EQE (%) | EL λₘₐₓ (nm) | FWHM (nm) |
|---|---|---|---|---|
| Ref. 1 | 3.5 | 3.3 | 460 | 73 |
| Ref. 2 | 3.9 | 4.1 | 452 | 51 |
| Ref. 3 | 3.8 | 3.8 | 448 | 52 |
| Ex. 1 | 4.1 | 6.3 | 466 | 63 |
| Ex. 2 | 4 | 9.6 | 466 | 60 |

As indicated in Table 1, compared to the OLEDs fabricated in Comparative Examples 1-3, in the OLEDs fabricated in Examples 1-2, EQE was improved by maximally 191.0%. The OLED including the Compound 1-1 and/or Compound 1-2 with excellent luminous efficiency can be realized.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. An organic light emitting diode, comprising:
a first electrode;
a second electrode facing the first electrode, and
an emissive layer disposed between the first electrode and the second electrode, and comprising one or more emitting material layers,
wherein at least one emitting material layer comprises a first compound, and
wherein the first compound comprises an organic compound having the following structure of Chemical Formula 1: 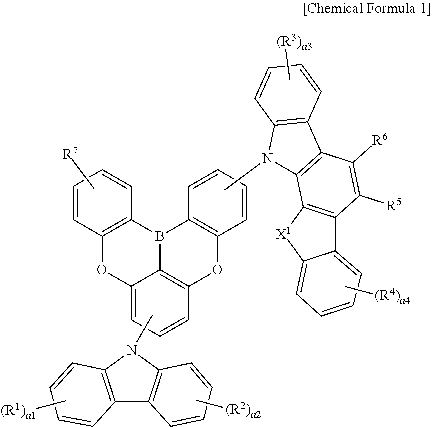
wherein, in Chemical Formula 1,
each of R¹ and R² is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹ is identical to or different from each other when a1 is 2, 3 or 4 and each R² is identical to or different from each other when a2 is 2, 3 or 4:
each of R³ and R⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R³ is identical to or different from each other when a3 is 2, 3 or 4 and each R⁴ is identical to or different from each other when a4 is 2, 3 or 4, or
optionally, two adjacent R³ when a3 is 2, 3 or 4 and/or two adjacent R⁴ when a4 is 2, 3 or 4 are further linked to form an unsubstituted or substituted C₃-C₂₀ alicyclic ring, an unsubstituted or substituted C₃-C₂₀ hetero alicyclic ring, an unsubstituted or substituted C₆-C₃₀ aromatic ring or an unsubstituted or substituted C₃-C₂₀ hetero aromatic ring;
R⁵ is an unsubstituted or substituted C₁-C₂₀ alkyl group;
R⁶ is hydrogen, an unsubstituted or substituted C₆-C₃₀ aryl group or an unsubstituted or substituted C₃-C₃₀ hetero aryl group;
R⁷ is an unsubstituted or substituted C₆-C₃₀ aryl group or an unsubstituted or substituted C₃-C₃₀ hetero aryl group;
X¹ is CR⁹R¹⁰, NR⁹, O or S, where each of R⁹ and R¹⁰ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of a1, a2, a3 and a4 is independently 0, 1, 2, 3 or 4; and
a dotted line indicates a fused position.

2. The organic light emitting diode of claim 1, wherein the first compound comprises an organic compound having the following structure of Chemical Formula 2: 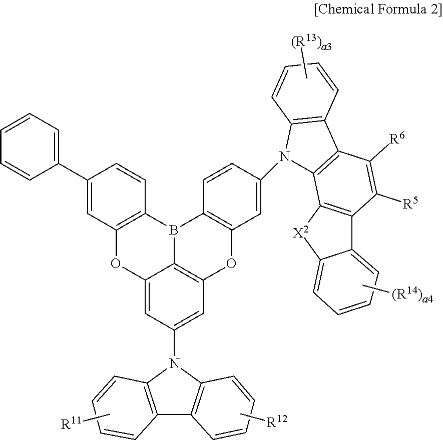
wherein, in Chemical Formula 2,
each of R⁵, R⁶, a3 and a4 is a same as defined in Chemical Formula 1;
each of R¹¹ and R¹² is independently hydrogen or an unsubstituted or substituted C₁-C₂₀ alkyl group;
each of R¹³ and R¹⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹³ is identical to or different from each other when a3 is 2, 3 or 4 and each R¹⁴ is identical to or different from each other when a4 is 2, 3 or 4, or
optionally, two adjacent R¹³ when a3 is 2, 3 or 4 and/or two adjacent R¹⁴ when a4 is 2, 3 or 4 are further linked to form a fused ring having the following structure of Chemical Formula 3;
X² is O or S;
a dotted line indicates a position to which the ring of Chemical Formula 3 is fused, 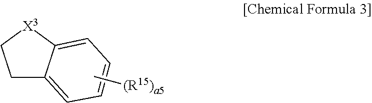
wherein, in Chemical Formula 3,
R¹⁵ is independently an unsubstituted or substituted C₁-C₂₀ alkyl group, where each R¹⁵ is identical to or different from each other when a5 is 2, 3 or 4;
X³ is CR¹⁶R¹⁷, NR¹⁶, O or S, where each of R¹⁶ and R¹⁷ is independently an unsubstituted or substituted C₁-C₂₀ alkyl group, an unsubstituted or substituted C₆-C₃₀ aryl group or an unsubstituted or substituted C₃-C₃₀ hetero aryl group;
a5 is 0, 1, 2, 3 or 4; and
a dotted line indicates a position to which the ring of Chemical Formula 2 is fused.

3. The organic light emitting diode of claim 1, wherein the first compound is at least one of the following organic compounds.

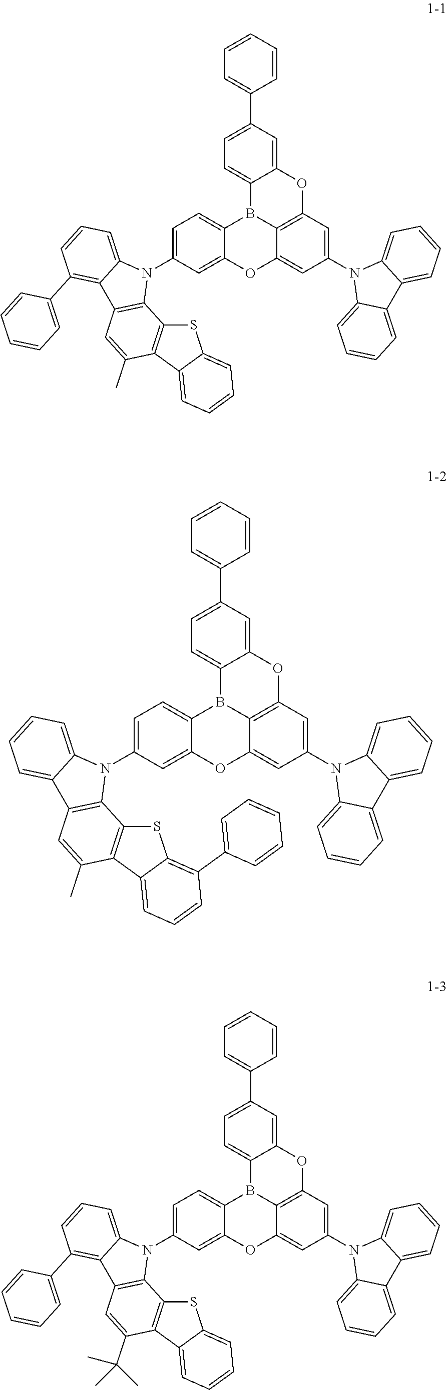 [SMILES: Cc1cc2c3c(-c4ccccc4)cccc3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3c(-c4ccccc4)cccc3c12 ; CC(C)(C)c1cc2c3c(-c4ccccc4)cccc3n(-c3ccc4c(c3)Oc3cc(-n5c6ccccc6c6ccccc65)cc5c3B4c3ccc(-c4ccccc4)cc3O5)c2c2sc3ccccc3c12]

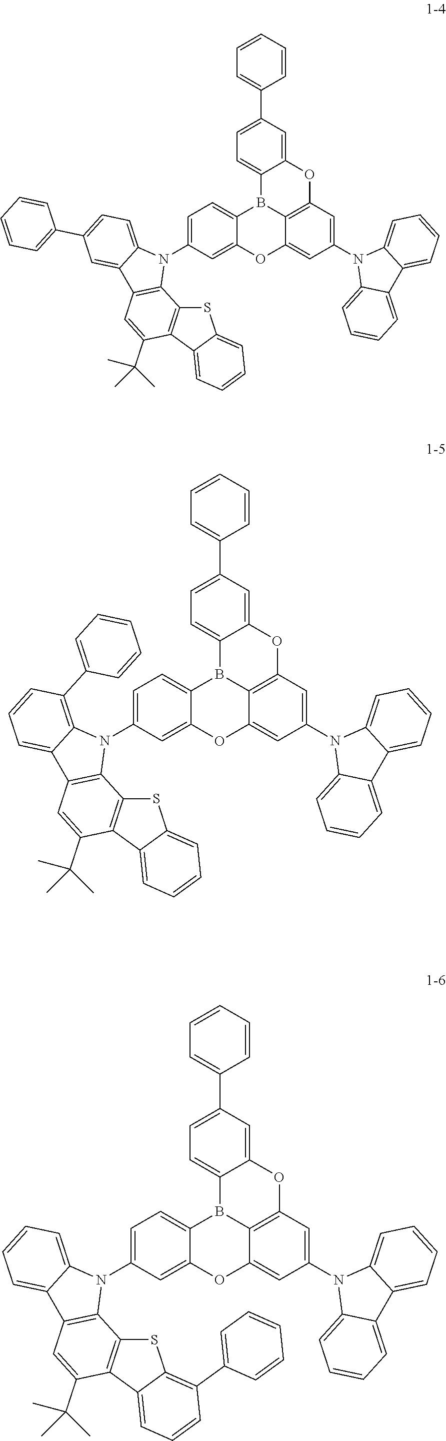 [SMILES: CC(C)(C)c1cc2c3cc(-c4ccccc4)ccc3n(-c3ccc4c(c3)Oc3cc(-n5c6ccccc6c6ccccc65)cc5c3B4c3ccc(-c4ccccc4)cc3O5)c2c2sc3ccccc3c12 ; CC(C)(C)c1cc2c3cccc(-c4ccccc4)c3n(-c3ccc4c(c3)Oc3cc(-n5c6ccccc6c6ccccc65)cc5c3B4c3ccc(-c4ccccc4)cc3O5)c2c2sc3ccccc3c12 ; CC(C)(C)c1cc2c3ccccc3n(-c3ccc4c(c3)Oc3cc(-n5c6ccccc6c6ccccc65)cc5c3B4c3ccc(-c4ccccc4)cc3O5)c2c2sc3c(-c4ccccc4)cccc3c12]

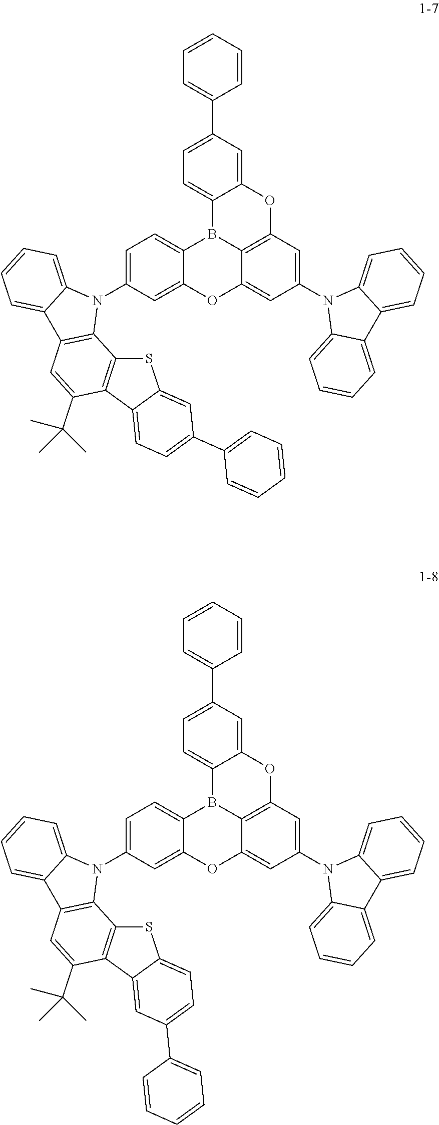 [SMILES: CC(C)(C)c1cc2c3ccccc3n(-c3ccc4c(c3)Oc3cc(-n5c6ccccc6c6ccccc65)cc5c3B4c3ccc(-c4ccccc4)cc3O5)c2c2sc3cc(-c4ccccc4)ccc3c12 ; CC(C)(C)c1cc2c3ccccc3n(-c3ccc4c(c3)Oc3cc(-n5c6ccccc6c6ccccc65)cc5c3B4c3ccc(-c4ccccc4)cc3O5)c2c2sc3ccc(-c4ccccc4)cc3c12]

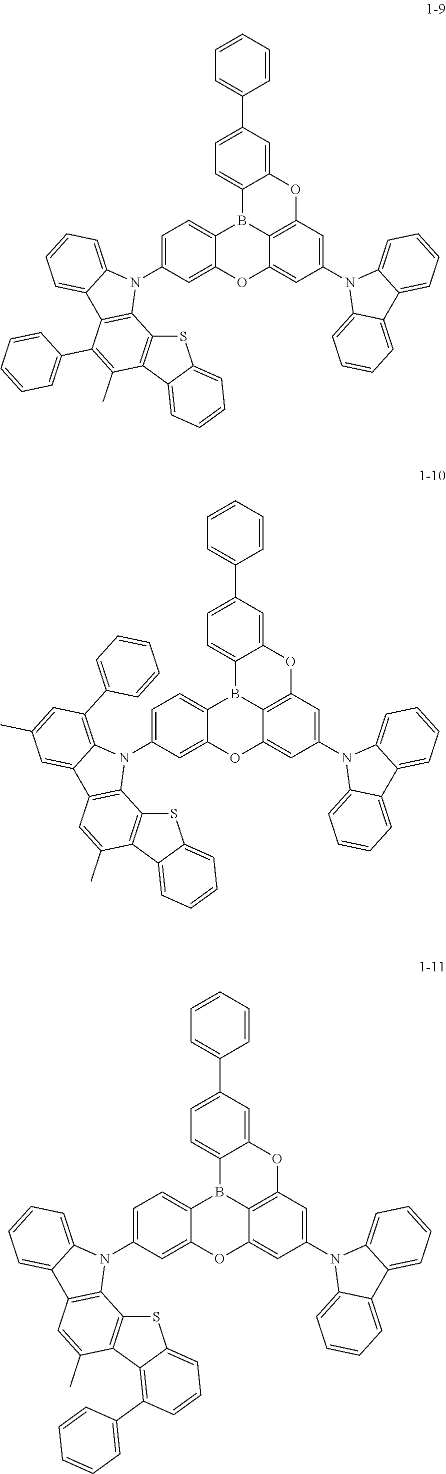 [SMILES: Cc1c(-c2ccccc2)c2c3ccccc3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc(-c2ccccc2)c2c(c1)c1cc(C)c3c4ccccc4sc3c1n2-c1ccc2c(c1)Oc1cc(-n3c4ccccc4c4ccccc43)cc3c1B2c1ccc(-c2ccccc2)cc1O3 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3cccc(-c4ccccc4)c3c12]

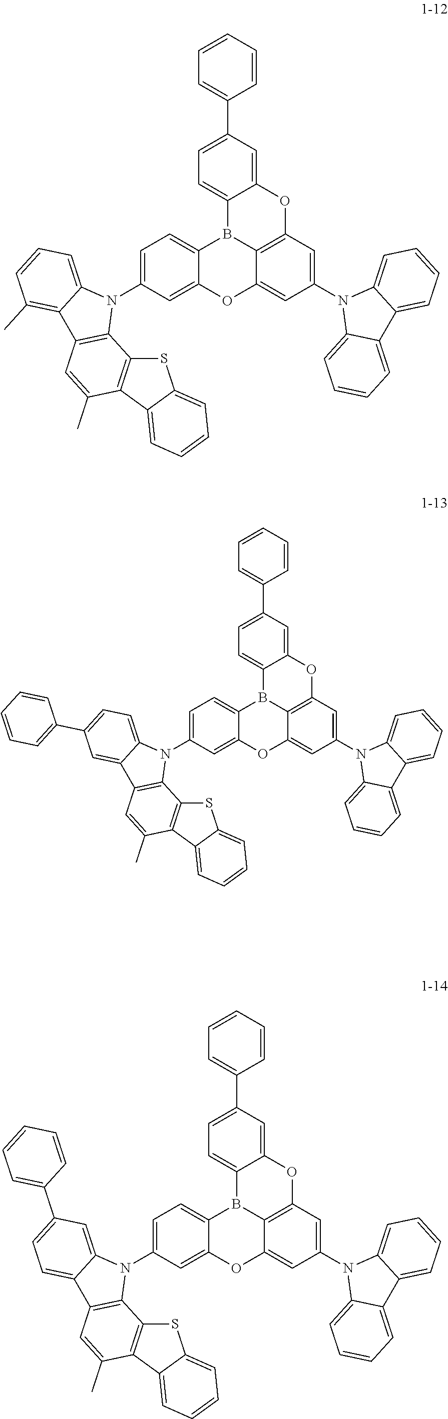 [SMILES: Cc1cc2c3c(C)cccc3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3cc(-c4ccccc4)ccc3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3ccc(-c4ccccc4)cc3n(-c3ccc4c(c3)Oc3cc(-n5c6ccccc6c6ccccc65)cc5c3B4c3ccc(-c4ccccc4)cc3O5)c2c2sc3ccccc3c12]

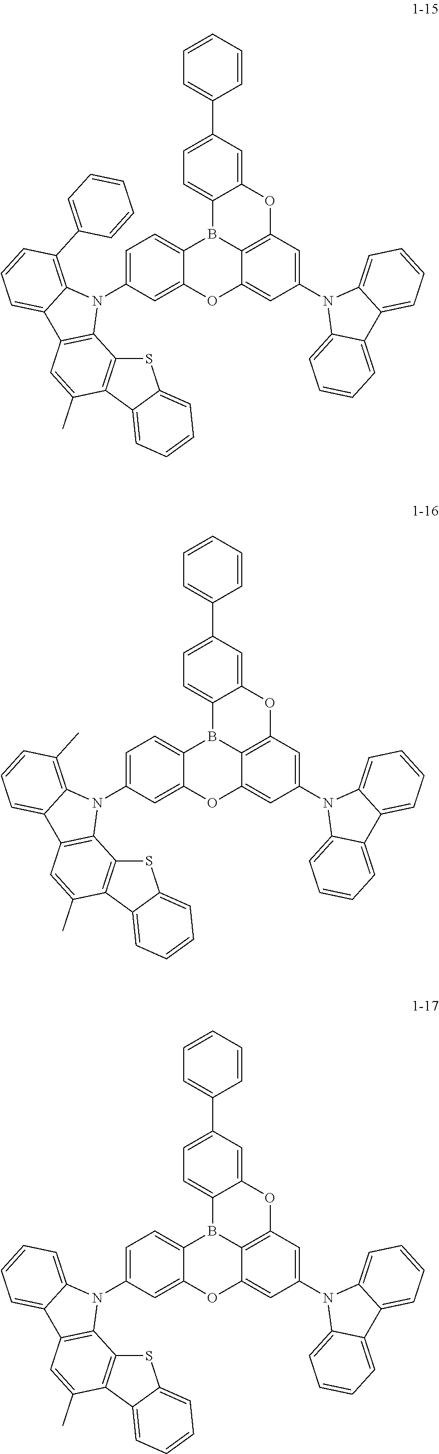 [SMILES: Cc1cc2c3cccc(-c4ccccc4)c3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3cccc(C)c3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3ccccc3c12]

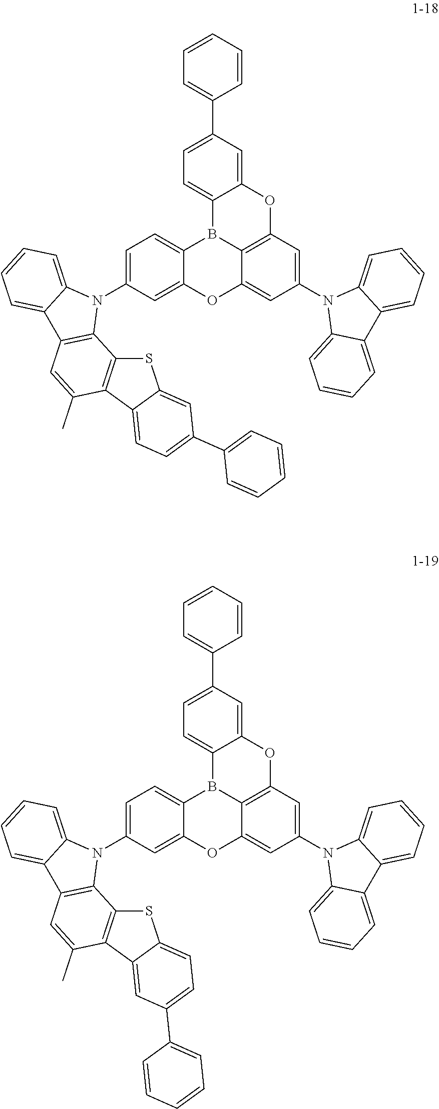 [SMILES: Cc1cc2c3ccccc3n(-c3ccc4c(c3)Oc3cc(-n5c6ccccc6c6ccccc65)cc5c3B4c3ccc(-c4ccccc4)cc3O5)c2c2sc3cc(-c4ccccc4)ccc3c12 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3ccc(-c4ccccc4)cc3c12]

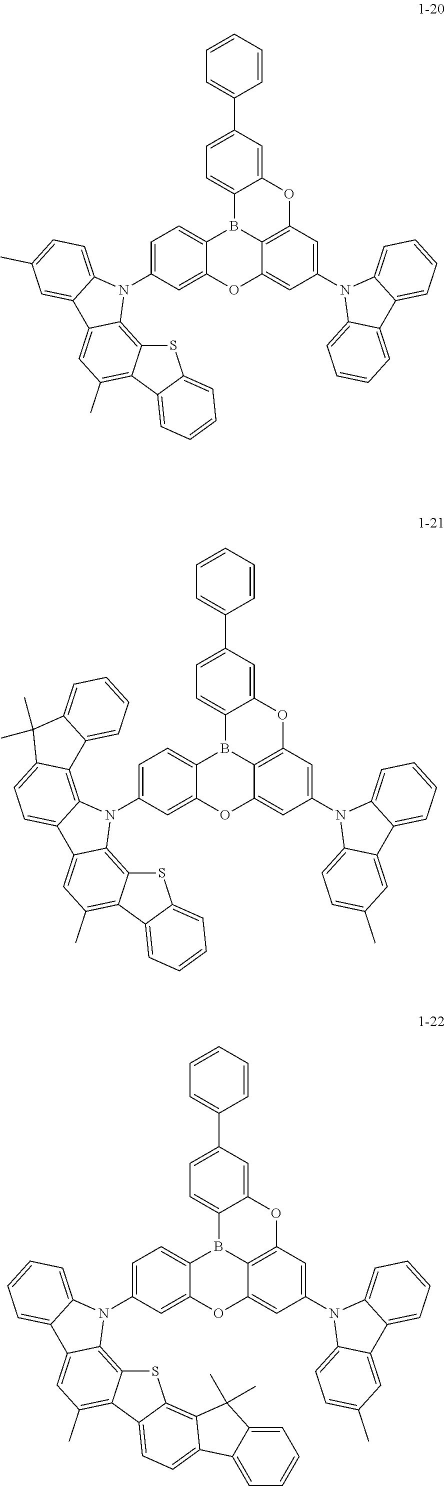 [SMILES: Cc1ccc2c(c1)c1cc(C)c3c4ccccc4sc3c1n2-c1ccc2c(c1)Oc1cc(-n3c4ccccc4c4ccccc43)cc3c1B2c1ccc(-c2ccccc2)cc1O3 ; Cc1ccc2c(c1)c1ccccc1n2-c1cc2c3c(c1)Oc1cc(-n4c5c6c(ccc5c5cc(C)c7c8ccccc8sc7c54)C(C)(C)c4ccccc4-6)ccc1B3c1ccc(-c3ccccc3)cc1O2 ; Cc1ccc2c(c1)c1ccccc1n2-c1cc2c3c(c1)Oc1cc(-n4c5ccccc5c5cc(C)c6c7ccc8c(c7sc6c54)C(C)(C)c4ccccc4-8)ccc1B3c1ccc(-c3ccccc3)cc1O2]

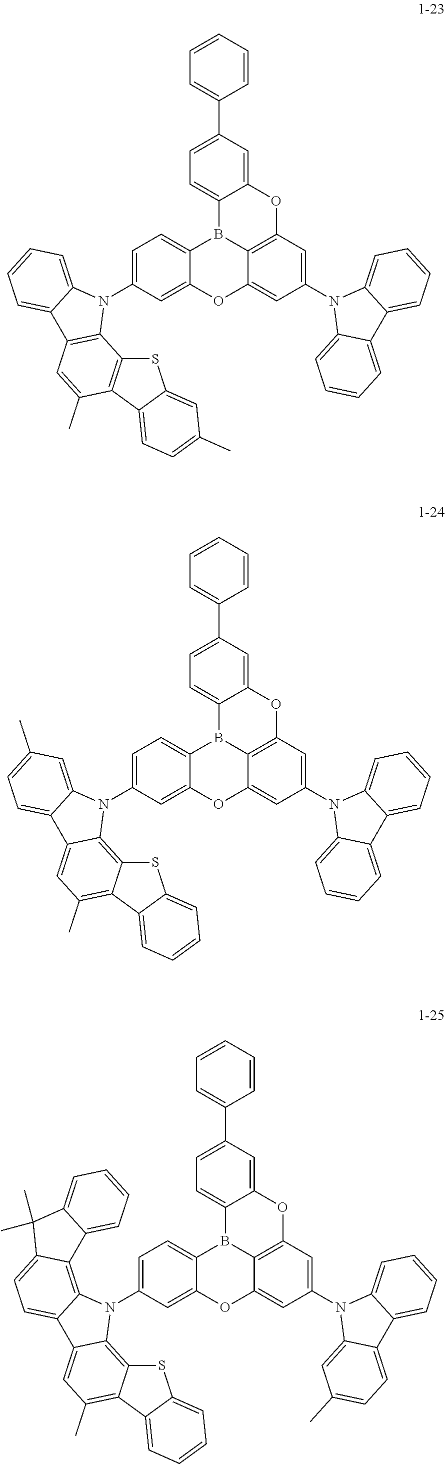 [SMILES: Cc1ccc2c(c1)sc1c2c(C)cc2c3ccccc3n(-c3ccc4c(c3)Oc3cc(-n5c6ccccc6c6ccccc65)cc5c3B4c3ccc(-c4ccccc4)cc3O5)c21 ; Cc1ccc2c3cc(C)c4c5ccccc5sc4c3n(-c3ccc4c(c3)Oc3cc(-n5c6ccccc6c6ccccc65)cc5c3B4c3ccc(-c4ccccc4)cc3O5)c2c1 ; Cc1ccc2c3ccccc3n(-c3cc4c5c(c3)Oc3cc(-n6c7c8c(ccc7c7cc(C)c9c%10ccccc%10sc9c76)C(C)(C)c6ccccc6-8)ccc3B5c3ccc(-c5ccccc5)cc3O4)c2c1]

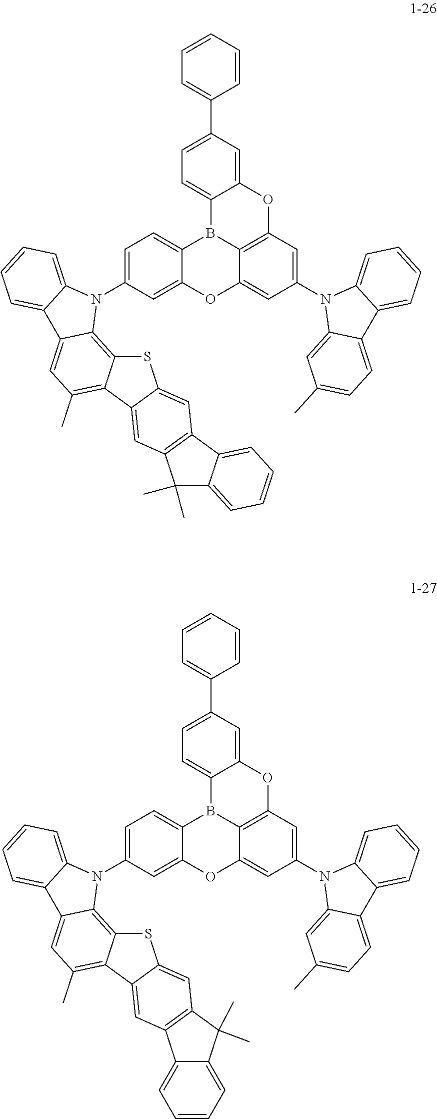 [SMILES: Cc1ccc2c3ccccc3n(-c3cc4c5c(c3)Oc3cc(-n6c7ccccc7c7cc(C)c8c9cc%10c(cc9sc8c76)-c6ccccc6C%10(C)C)ccc3B5c3ccc(-c5ccccc5)cc3O4)c2c1 ; Cc1ccc2c3ccccc3n(-c3cc4c5c(c3)Oc3cc(-n6c7ccccc7c7cc(C)c8c9cc%10c(cc9sc8c76)C(C)(C)c6ccccc6-%10)ccc3B5c3ccc(-c5ccccc5)cc3O4)c2c1]

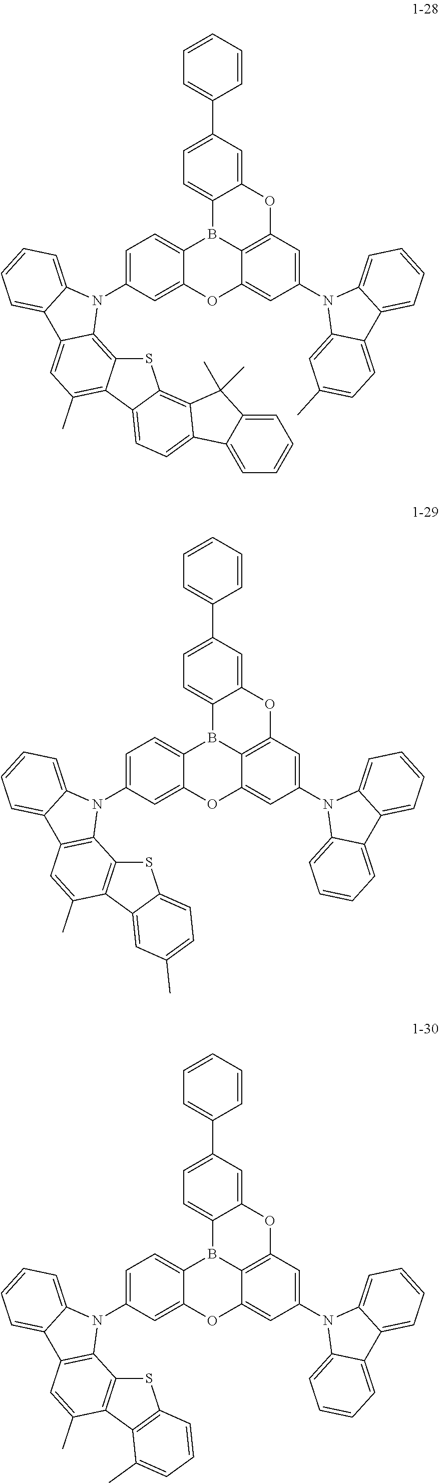 [SMILES: Cc1ccc2c3ccccc3n(-c3cc4c5c(c3)Oc3cc(-n6c7ccccc7c7cc(C)c8c9ccc%10c(c9sc8c76)C(C)(C)c6ccccc6-%10)ccc3B5c3ccc(-c5ccccc5)cc3O4)c2c1 ; Cc1ccc2sc3c(c(C)cc4c5ccccc5n(-c5ccc6c(c5)Oc5cc(-n7c8ccccc8c8ccccc87)cc7c5B6c5ccc(-c6ccccc6)cc5O7)c43)c2c1 ; Cc1cccc2sc3c(c(C)cc4c5ccccc5n(-c5ccc6c(c5)Oc5cc(-n7c8ccccc8c8ccccc87)cc7c5B6c5ccc(-c6ccccc6)cc5O7)c43)c12]

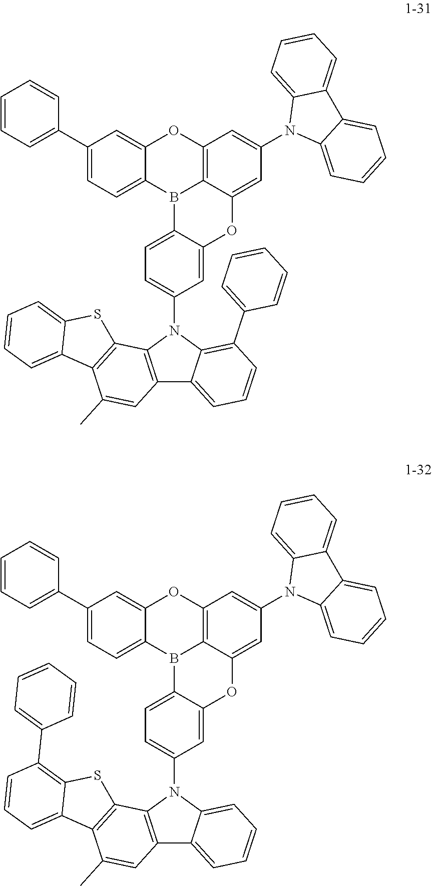 [SMILES: Cc1cc2c3cccc(-c4ccccc4)c3n(-c3ccc4c(c3)Oc3cc(-n5c6ccccc6c6ccccc65)cc5c3B4c3ccc(-c4ccccc4)cc3O5)c2c2sc3ccccc3c12 ; Cc1cc2c3ccccc3n(-c3ccc4c(c3)Oc3cc(-n5c6ccccc6c6ccccc65)cc5c3B4c3ccc(-c4ccccc4)cc3O5)c2c2sc3c(-c4ccccc4)cccc3c12]

4. The organic light emitting diode of claim 1, wherein the at least one emitting material layer further comprises a second compound.

5. The organic light emitting diode of claim 4, wherein the second compound comprises an organic compound having the following structure of Chemical Formula 5: 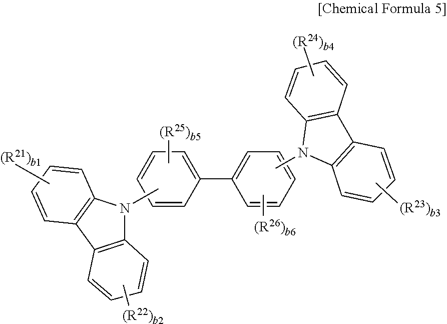
wherein, in Chemical Formula 5,
each of R²¹, R²², R²³, R²⁴, R²⁵ and R²⁶ is independently a cyano group, an unsubstituted or substituted C₁-C₂₀ alkyl group, an unsubstituted or substituted C₆-C₃₀ aryl group or an unsubstituted or substituted C₃-C₃₀ hetero aryl group, where each R²¹ is identical to or different from each other when b1 is 2, 3 or 4, each R²² is identical to or different from each other when b2 is 2, 3 or 4, each R²³ is identical to or different from each other when b3 is 2, 3 or 4, each R²⁴ is identical to or different from each other when b4 is 2, 3 or 4, each R²⁵ is identical to or different from each other when b5 is 2, 3 or 4, and each R²⁶ is identical to or different from each other when b6 is 2, 3 or 4; and
each of b1, b2, b3, b4, b5 and b6 is independently 0, 1, 2, 3 or 4.

6. The organic light emitting diode of claim 4, wherein the second compound comprises an organic compound having the following structure of Chemical Formula 7: 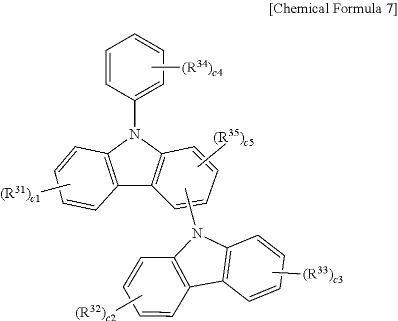
wherein, in Chemical Formula 7,
each of R³¹, R³², R³³, R³⁴ and R³⁵ is independently a cyano group, an unsubstituted or substituted C₁-C₂₀ alkyl group, an unsubstituted or substituted C₆-C₃₀ aryl group or an unsubstituted or substituted C₃-C₃₀ hetero aryl group, an unsubstituted or substituted C₆-C₃₀ triaryl silyl group or an unsubstituted or substituted C₆-C₃₀ triaryl germanyl group, where each R³¹ is identical to or different from each other when c1 is 2, 3 or 4, each R³² is identical to or different from each other when c2 is 2, 3 or 4, each R³³ is identical to or different from each other when c3 is 2, 3 or 4, where each R³⁴ is identical to or different from each other when c4 is 2, 3, 4 or 5, and each R³⁵ is identical to or different from each other when c5 is 2 or 3;
each of c1, c2 and c3 is independently 0, 1, 2, 3 or 4;
c4 is 0, 1, 2, 3, 4 or 5; and
c5 is 0, 1, 2 or 3.

7. The organic light emitting diode of claim 1, wherein the emissive layer comprises:
a first emitting part disposed between the first electrode and the second electrode;
a second emitting part disposed between the first emitting part and the second electrode; and
a first charge generation layer disposed between the first emitting part and the second emitting part, and
wherein at least one of the first emitting part and the second emitting part comprises the at least one emitting material layer.

8. The organic light emitting diode of claim 7, wherein the first emitting part comprises a first emitting material layer and wherein the first emitting material layer comprises the at least one emitting material layer.

9. The organic light emitting diode of claim 8, wherein the second emitting part comprises a second emitting material layer, wherein the second emitting material layer comprises:
a first layer disposed between the first charge generation layer and the second electrode; and
a second layer disposed between the first layer and the second electrode,
wherein one of the first layer and the second layer is a red emitting material layer, and
wherein the other of the first layer and the second layer is a green emitting material layer.

10. The organic light emitting diode of claim 9, wherein the second emitting material layer further comprises a third layer disposed between the first layer and the second layer, and
wherein the third layer is a yellow-green emitting material layer.

11. The organic light emitting diode of claim 7, wherein the emissive layer further comprises:
a third emitting part disposed between the second emitting part and the second electrode; and
a second charge generation layer disposed between the second emitting part and the third emitting part.

12. The organic light emitting diode of claim 11, wherein at least one of the first emitting part and the third emitting part comprises the at least one emitting material layer.

13. The organic light emitting diode of claim 12, wherein the first emitting part comprises a first emitting material layer and the third emitting part comprises a third emitting material layer, and
wherein each of the first emitting material layer and the third emitting material layer comprises the at least one emitting material layer.

14. The organic light emitting diode of claim 12, wherein the second emitting part comprises a second emitting material layer, wherein the second emitting material layer comprises:
a first layer disposed between the first charge generation layer and the second electrode; and
a second layer disposed between the first layer and the second electrode,
wherein one of the first layer and the second layer is a red emitting material layer, and
wherein the other of the first layer and the second layer is a green emitting material layer.

15. The organic light emitting diode of claim 14, wherein the second emitting material layer further comprises a third layer disposed between the first layer and the second layer, and
wherein the third layer is a yellow-green emitting material layer.

16. The organic light emitting diode of claim 6, wherein the unsubstituted or substituted C₁-C₂₀ alkyl group comprises an unsubstituted or substituted C₆-C₃₀ triaryl methyl group.

17. The organic light emitting diode of claim 4, wherein the second compound is at least one of the following organic compounds:

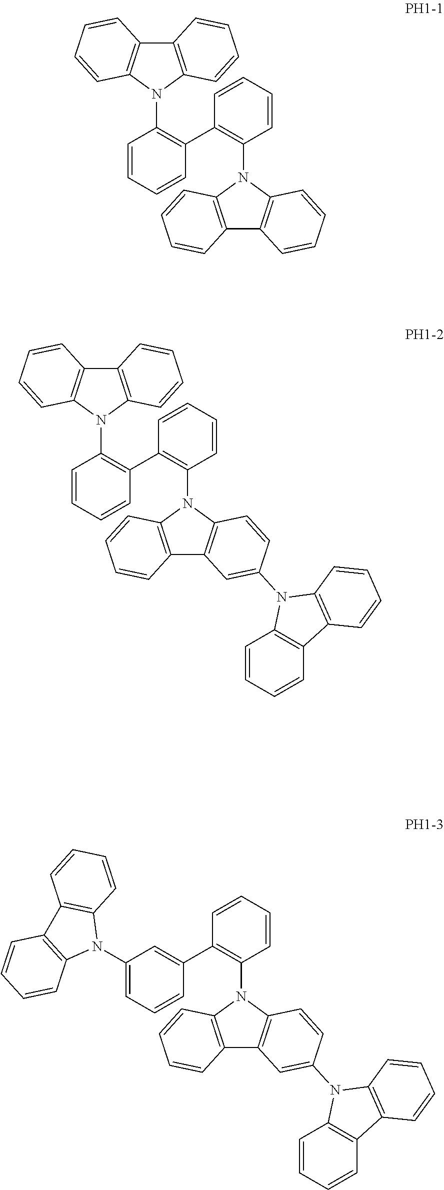 [SMILES: c1ccc(-n2c3ccccc3c3ccccc32)c(-c2ccccc2-n2c3ccccc3c3ccccc32)c1 ; c1ccc(-n2c3ccccc3c3ccccc32)c(-c2ccccc2-n2c3ccccc3c3cc(-n4c5ccccc5c5ccccc54)ccc32)c1 ; c1cc(-c2ccccc2-n2c3ccccc3c3cc(-n4c5ccccc5c5ccccc54)ccc32)cc(-n2c3ccccc3c3ccccc32)c1]

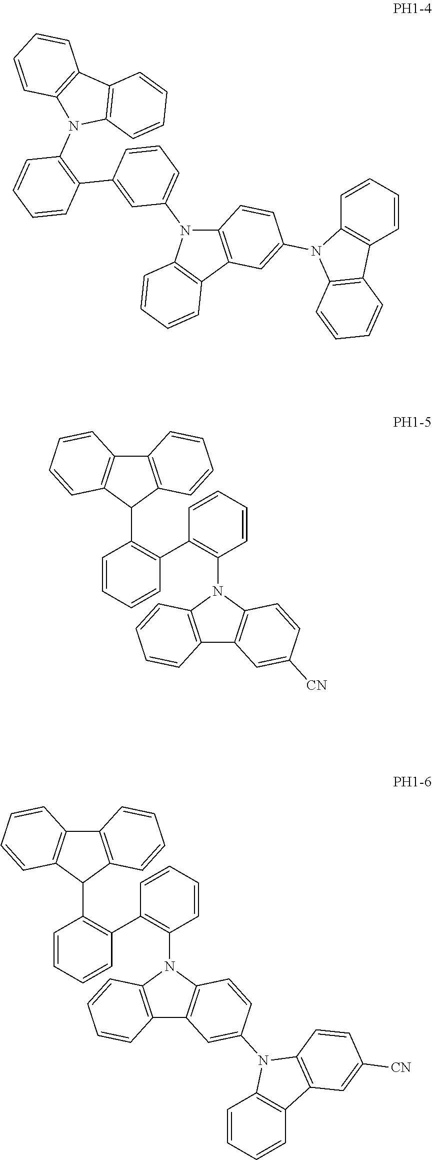 [SMILES: c1cc(-c2ccccc2-n2c3ccccc3c3ccccc32)cc(-n2c3ccccc3c3cc(-n4c5ccccc5c5ccccc54)ccc32)c1 ; N#Cc1ccc2c(c1)c1ccccc1n2-c1ccccc1-c1ccccc1C1c2ccccc2-c2ccccc21 ; N#Cc1ccc2c(c1)c1ccccc1n2-c1ccc2c(c1)c1ccccc1n2-c1ccccc1-c1ccccc1C1c2ccccc2-c2ccccc21]

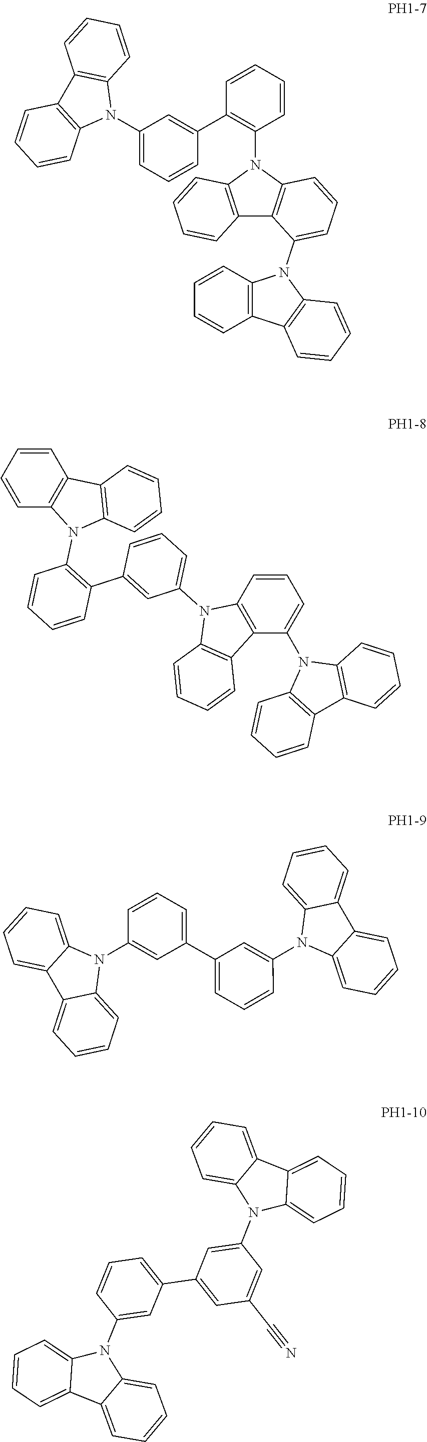 [SMILES: c1cc(-c2ccccc2-n2c3ccccc3c3c(-n4c5ccccc5c5ccccc54)cccc32)cc(-n2c3ccccc3c3ccccc32)c1 ; c1cc(-c2ccccc2-n2c3ccccc3c3ccccc32)cc(-n2c3ccccc3c3c(-n4c5ccccc5c5ccccc54)cccc32)c1 ; c1cc(-c2cccc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3ccccc32)c1]

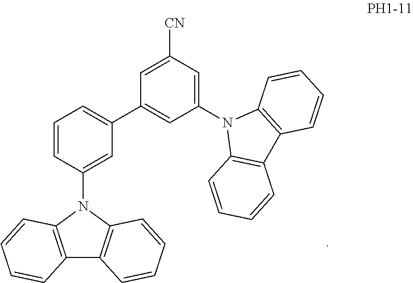 [SMILES: N#Cc1cc(-c2cccc(-n3c4ccccc4c4ccccc43)c2)cc(-n2c3ccccc3c3ccccc32)c1]

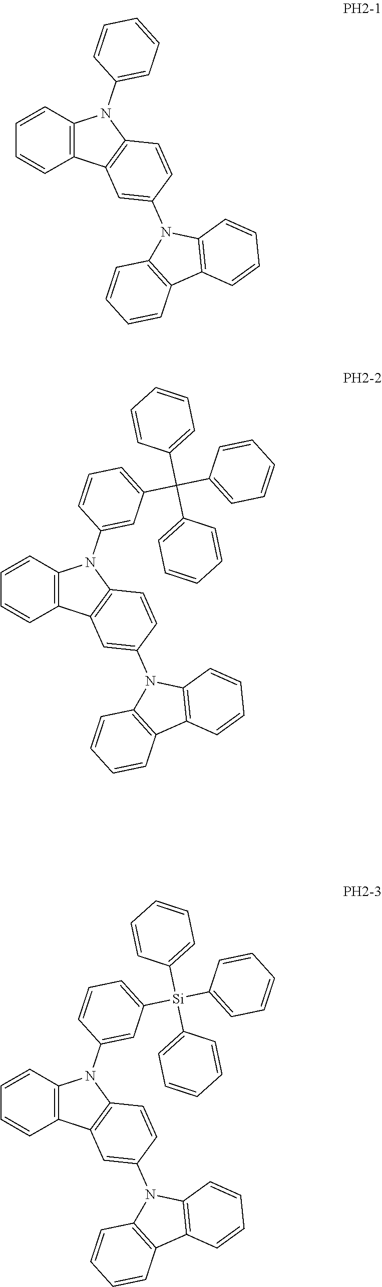 [SMILES: c1ccc(-n2c3ccccc3c3cc(-n4c5ccccc5c5ccccc54)ccc32)cc1 ; c1ccc(C(c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-n3c4ccccc4c4cc(-n5c6ccccc6c6ccccc65)ccc43)c2)cc1]

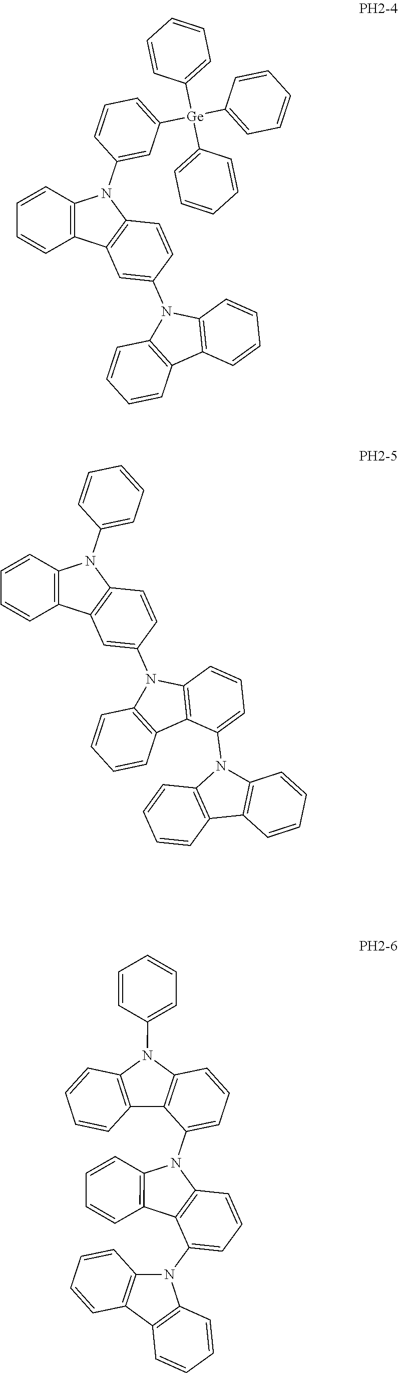

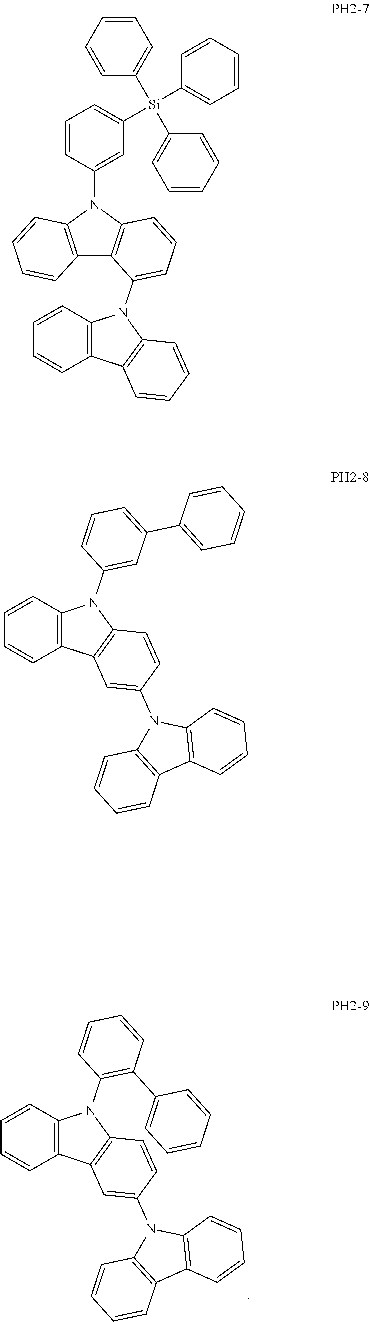 [SMILES: c1ccc([Si](c2ccccc2)(c2ccccc2)c2cccc(-n3c4ccccc4c4c(-n5c6ccccc6c6ccccc65)cccc43)c2)cc1 ; c1ccc(-c2cccc(-n3c4ccccc4c4cc(-n5c6ccccc6c6ccccc65)ccc43)c2)cc1 ; c1ccc(-c2ccccc2-n2c3ccccc3c3cc(-n4c5ccccc5c5ccccc54)ccc32)cc1]

18. The organic light emitting diode of claim 4, wherein the second compound comprises 9-(3-(9H-carbazol-9-yl)phenyl)-9H-carbazole-3-carbonitrile, 4,4′-bis(N-carbazolyl)-1,1′-biphenyl, 3,3′-bis(N-carbazolyl)-1,1′-biphenyl, 1,3-Bis(carbazol-9-yl)benzene, Bis[2-(diphenylphosphino)phenyl]ether oxide, (oxybis(3-(tert-butyl)-6,1-phenylene))bis(diphenylphosphine oxide), 2,8-bis(diphenylphosphoryl)dibenzothiophene, 1,3,5-Tri[(3-pyridyl)-phen-3-yl]benzene, 2,6-Di(9H-carbazol-9-yl)pyridine, 2,8-di(9H-carbazol-9-yl)dibenzothiophene, 3′,5′-Di(carbazol-9-yl)-[1,1′-biphenyl]-3,5-dicarbonitrile, 4′-(9H-carbazol-9-yl)biphenyl-3,5-dicarbonitrile, 3′-(9H-carbazol-9-yl)biphenyl-3,5-dicarbonitrile, Diphenyl-4-triphenylsilyl-phenylphosphine oxide, 9-(9-phenyl-9H-carbazol-6-yl)-9H-carbazole, 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-Diphenyl-9H,9′H-3,3′-bicarbazole, 9,9′-Di(4-biphenyl)-9H,9′H-3,3′-bicabazole, 1,3,5-Tris(carbazole-9-yl)benzene, Tris(4-carbazoyl-9-yl-phenyl)amine, 4,4′-Bis(carbazole-9-yl)-2,2′-dimethylbiphenyl, 2,7-Bis(carbazole-9-yl)-9,9-dimethylfluorene, 2,2′,7,7′-Tetrakis(carbazole-9-yl)-9,9-spirofluorene, 3,6-Bis(carbazole-9-yl)-9-(2-ethyl-hexyl)-9H-carbazole, o-CzCN(1), m-CzCN(1), 4CzCzCN, 4CzCNCzCN, 24CzCzCN, 24CzCNCzCN, mBFCzCN, dBFCzCN, m-CzCNDMT, p-CzCNDMT, 2,4-2CzBN, 2,6-2CzBN, 3,5-2CzBN, 3CzBN, CNPhCz, DCNPhCz, o-CzCN, m-CzCN, p-CzCN, oCzBN, mCzBN, pCzBN, CNCzCN1, CNCACN2, CnCzCN3, CnCzCN4, CzDBTCN, DBTCzCN, mCPCz, BPRTZ, MBPRTZ, 3CzFDPhTz, TDPA-TRZ, 3-(4,6-bis(3-(triphenylsilyl)phenyl)-1,3,5-triazine-2-yl)benzonitrile and/or combinations thereof.

19. An organic light emitting device, comprising:
a substrate; and
the organic light emitting diode of claim 1 over the substrate.

20. An organic light emitting diode, comprising:
a first electrode;
a second electrode facing the first electrode; and
an emissive layer disposed between the first electrode and the second electrode, and comprising one or more emitting material layers,
wherein at least one emitting material layer comprises a first compound, and
wherein the first compound comprises an organic compound having the following structure of Chemical Formula 11: 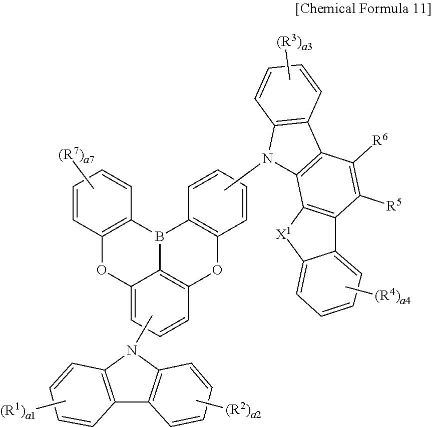
wherein, in Chemical Formula 11,
each of R¹ and R² is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹ is identical to or different from each other when a1 is 2, 3 or 4 and each R² is identical to or different from each other when a2 is 2, 3 or 4;
each of R³ and R⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R³ is identical to or different from each other when a3 is 2, 3 or 4 and each R⁴ is identical to or different from each other when a4 is 2, 3 or 4, or
optionally, two adjacent R³ when a3 is 2, 3 or 4 and/or two adjacent R⁴ when a4 is 2, 3 or 4 are further linked to form an unsubstituted or substituted C₃-C₂₀ alicyclic ring, an unsubstituted or substituted C₃-C₂₀ hetero alicyclic ring, an unsubstituted or substituted C₆-C₃₀ aromatic ring or an unsubstituted or substituted C₃-C₂₀ hetero aromatic ring;
R⁵ is an unsubstituted or substituted C₁-C₂₀ alkyl group;
R⁶ is hydrogen, an unsubstituted or substituted C₆-C₃₀ aryl group or an unsubstituted or substituted C₃-C₃₀ hetero aryl group;
R⁷ is hydrogen, an unsubstituted or substituted C₁-C₂₀ alkyl group; an unsubstituted or substituted C₆-C₃₀ aryl group or an unsubstituted or substituted C₃-C₃₀ hetero aryl group, where each R⁷ is identical to or different from each other when a7 is 2, 3 or 4;
X¹ is CR⁹R¹⁰, NR⁹, O or S, where each of R⁹ and R¹⁰ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of a1, a2, a3, a4 and a7 is independently 0, 1, 2, 3 or 4; and
a dotted line indicates a fused position.

21. The organic light emitting diode of claim 20, wherein the first compound comprises an organic compound having the following structure of Chemical Formula 12: 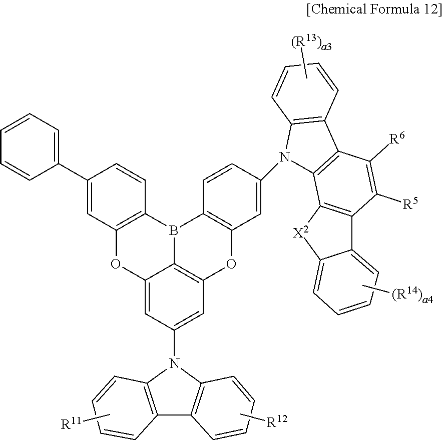
wherein, in Chemical Formula 12,
each of R⁵, R⁶, a3 and a4 is a same as defined in Chemical Formula 11;
each of R¹¹ and R¹² is independently hydrogen, an unsubstituted or substituted C₁-C₂₀ alkyl group, or an unsubstituted or substituted C₆-C₃₀ aryl group;
each of R¹³ and R¹⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹³ is identical to or different from each other when a3 is 2, 3 or 4 and each R¹⁴ is identical to or different from each other when a4 is 2, 3 or 4, or
optionally, two adjacent R¹³ when a3 is 2, 3 or 4 and/or two adjacent R¹⁴ when a4 is 2, 3 or 4 are further linked to form a fused ring having the following structure of Chemical Formula 3;
X² is O or S;
a dotted line indicates a position to which the ring of Chemical Formula 3 is fused, 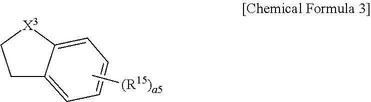
wherein, in Chemical Formula 3,
R¹⁵ is independently an unsubstituted or substituted C₁-C₂₀ alkyl group, where Each R¹⁵ is identical to or different from each other when a5 is 2, 3 or 4;
X³ is CR¹⁶R¹⁷, NR¹⁶, O or S, where each of R¹⁶ and R¹⁷ is independently an unsubstituted or substituted C₁-C₂₀ alkyl group, an unsubstituted or substituted C₆-C₃₀ aryl group or an unsubstituted or substituted C₃-C₃₀ hetero aryl group;
a5 is 0, 1, 2, 3 or 4; and
a dotted line indicates a position to which the ring of Chemical Formula 2 is fused.

22. The organic light emitting diode of claim 20, wherein the first compound comprises an organic compound having the following structure of Chemical Formula 13: 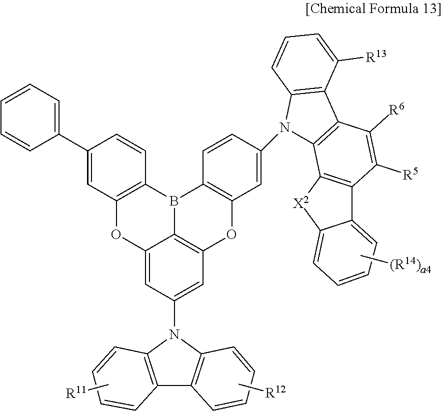
wherein, in Chemical Formula 13,
each of R⁵, R⁶ and a4 is a same as defined in Chemical Formula 11;
each of R¹¹ to R¹³ is independently hydrogen, an unsubstituted or substituted C₁-C₂₀ alkyl group, or an unsubstituted or substituted C₆-C₃₀ aryl group;
R¹⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹⁴ is identical to or different from each other when a4 is 2, 3 or 4, or
optionally, two adjacent R¹⁴ when a4 is 2, 3 or 4 are further linked to form a fused ring having the structure of Chemical Formula 3 as defined in Chemical Formula 12.

23. The organic light emitting diode of claim 20, wherein the first compound comprises an organic compound having the following structure of Chemical Formula 14: 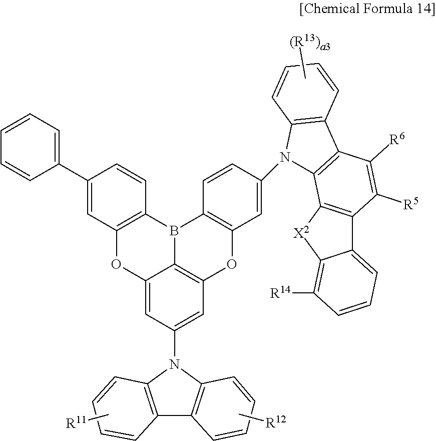
wherein, in Chemical Formula 13,
each of R⁵, R⁶ and a3 is a same as defined in Chemical Formula 11;
each of R¹¹, R¹³R¹² and R¹⁴ is independently hydrogen, an unsubstituted or substituted C₁-C₂₀ alkyl group, or an unsubstituted or substituted C₆-C₃₀ aryl group;
R¹³ is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹³ is identical to or different from each other when a3 is 2, 3 or 4, or
optionally, two adjacent R¹³ when a3 is 2, 3 or 4 are further linked to form a fused ring having the structure of Chemical Formula 3 as defined in Chemical Formula 12.

24. The organic light emitting diode of claim 22, wherein, in Chemical Formula 13,
R⁵ is a C₁-C₁₀ alkyl group; and/or
R⁶ is hydrogen; and/or
a3 is 0; and/or
a4 is 0, and/or
each of R¹¹ and R¹² is independently hydrogen or a C₁-C₁₀ alkyl group.

25. The organic light emitting diode of claim 23, wherein, in Chemical Formula 13,
R⁵ is a C₁-C₁₀ alkyl group; and/or
R⁶ is hydrogen; and/or
a3 is 0; and/or
a4 is 0; and/or
each of R¹¹ and R¹² is independently hydrogen or a C₁-C₁₀ alkyl group.
